(19) United States
(12) Patent Application Publication
(10) Pub. No.: US 2026/0223557 A1
(43) Pub. Date: Jul. 30, 2026

(54) DISPLAY DEVICE AND ELECTRONIC DEVICE INCLUDING THE SAME

(71) Applicant: Samsung Display Co., Ltd., Yongin-si (KR)

(72) Inventors: Hee Rim SONG, Yongin-si (KR); Su Kyo JUNG, Yongin-si (KR); Jae Won CHO, Yongin-si (KR); Hee Ju MOON, Yongin-si (KR)

(21) Appl. No.: 19/335,995

(22) Filed: Sep. 22, 2025

(30) Foreign Application Priority Data
Jan. 24, 2025 (KR) 10-2025-0011789

(51) Int. Cl. H10K 59/131; H10D 86/40; H10D 86/60; H10K 59/121; H10K 59/126

(52) U.S. Cl. CPC H10K 59/131; H10K 59/1213; H10K 59/1216; H10K 59/126; H10D 86/423; H10D 86/441; H10D 86/60

(57) ABSTRACT

A display device which includes a substrate including a display area where emission areas are arranged; a circuit layer on the substrate; and an element layer on the circuit layer. The circuit layer includes a light blocking conductive layer on the substrate; a buffer layer covering the light blocking conductive layer; a first semiconductor layer on the buffer layer; a first interlayer insulating layer on the first semiconductor layer; and a second semiconductor layer on the first interlayer insulating layer and including an oxide semiconductor material.

### CROSS-REFERENCE TO RELATED APPLICATION

This application claims priority to and the benefit of Korean Patent Application No. 10-2025-0011789 filed on Jan. 24, 2025, in the Korean Intellectual Property Office, the entire disclosure of which is incorporated by reference herein.

### BACKGROUND

### 1. Field

The present disclosure relates to a display device and an electronic device including the same.

### 2. Description of the Related Art

As the information society develops, the demand for display devices for displaying images has increased and diversified. For example, display devices have been applied to various electronic devices such as smartphones, digital cameras, laptop computers, navigation devices, and smart televisions.

The display devices may be flat panel display devices such as liquid crystal display devices, field emission display devices, or light emitting display devices. Here, the light emitting display device may include an organic light emitting display device including organic light emitting elements, an inorganic light emitting display device including inorganic light emitting elements such as inorganic semiconductors, and a micro light emitting display device including micro light emitting elements.

The organic light emitting display device displays an image using light emitting elements respectively including light emitting layers made of an organic light emitting material. As such, the organic light emitting display device implements image display using self-light emitting elements, and accordingly, may have relatively excellent performance in terms of power consumption, response speed, luminous efficiency, luminance, and wide viewing angle, and/or the like, compared to other display devices.

A display surface of the display device from which light is emitted may include a display area where an image is displayed and a non-display area, which is a peripheral area of the display area. Emission areas for emitting light of each luminance and color may be arranged in the display area.

### SUMMARY

The display device may include light emitting pixel drivers for transmitting driving currents to light emitting elements.

Each of the light emitting pixel drivers may include a first transistor for generating the driving current, and a channel portion of the first transistor may include an oxide semiconductor material.

When a data signal is transmitted to a gate electrode of the first transistor, a voltage difference between the gate electrode of the first transistor and a source electrode of the first transistor may become a threshold voltage or more, such that the first transistor may be turned on and a drain-source current of the first transistor may be generated as the driving current.

Because a magnitude of the drain-source current of the first transistor corresponds to the voltage difference between the gate electrode of the first transistor and the source electrode of the first transistor, the magnitude of the drain-source current of the first transistor may increase as a potential of the source electrode of the first transistor is maintained regardless of the data signal.

Accordingly, the light emitting pixel drivers may include a first capacitor electrically connected between the gate electrode of the first transistor and the source electrode of the first transistor and a second capacitor electrically connected between the source electrode of the first transistor and a constant voltage line.

In addition, as capacitance of the second capacitor is increased, the magnitude of the drain-source current of the first transistor may be increased, and thus, luminance of the light emitting element may be improved.

However, in order to increase the capacitance of the second capacitor for the improvement of the luminance, a width of the second capacitor may be increased, and thus, a resolution of the display device may be reduced.

Aspects and features of embodiments of the present disclosure relate to improving resolution and luminance of a display device by increasing capacitance of a second capacitor of the display device regardless of the resolution, and an electronic device including the same.

However, aspects and features of embodiments of the present disclosure are not restricted to those set forth herein. The above and other aspects of the present disclosure will become more apparent to one of ordinary skill in the art to which the present disclosure pertains by referencing the detailed description of the present disclosure given below.

According to one or more embodiments of the present disclosure, a display device includes a substrate including a display area where emission areas are arranged; a circuit layer on the substrate; and an element layer on the circuit layer. The circuit layer includes a light blocking conductive layer on the substrate; a buffer layer covering the light blocking conductive layer; a first semiconductor layer on the buffer layer; a first interlayer insulating layer on the first semiconductor layer; and a second semiconductor layer on the first interlayer insulating layer and including an oxide semiconductor material.

The element layer includes light emitting elements in the emission areas. The circuit layer includes light emitting pixel drivers respectively transmitting driving currents to the light emitting elements. Each of the light emitting pixel drivers includes a first transistor configured to generate the driving current. The first transistor includes a gate electrode, a channel portion overlapping the gate electrode, a first electrode portion connected to one side of the channel portion, and a second electrode portion connected to an other side of the channel portion. The channel portion, the first electrode portion, and the second electrode portion of the first transistor are at the second semiconductor layer.

Each of the light emitting pixel drivers further includes a second transistor electrically connected between a data line configured to transmit a data signal and the gate electrode of the first transistor; a third transistor electrically connected between a reference voltage line configured to transmit a reference voltage and the gate electrode of the first transistor; a fourth transistor electrically connected between an initialization voltage line configured to transmit an initialization voltage and one of the light emitting elements; a fifth transistor electrically connected between a first power line configured to transmit a first power and the first electrode portion of the first transistor; a sixth transistor electrically connected between the one of the light emitting elements and the second electrode portion of the first transistor; a first capacitor electrically connected between the gate electrode of the first transistor and the second electrode portion of the first transistor; and a second capacitor electrically connected between the first power line configured to transmit the first power and the second electrode portion of the first transistor. A channel portion, a first electrode portion and a second electrode portion of each of the second transistor, the third transistor and the fourth transistor are at the second semiconductor layer. A channel portion, a first electrode portion and a second electrode portion of each of the fifth transistor and the sixth transistor are at the first semiconductor layer.

The circuit layer further includes a first gate insulating layer covering the first semiconductor layer; a first gate conductive layer on the first gate insulating layer; a second gate insulating layer covering the first gate conductive layer; a second gate conductive layer between the second gate insulating layer and the first interlayer insulating layer; a third gate insulating layer covering the second semiconductor layer; and a third gate conductive layer located between the third gate insulating layer and the second interlayer insulating layer. Each of the light emitting pixel drivers further includes a first capacitor electrode at the first gate conductive layer and electrically connected to the gate electrode of the first transistor; a second capacitor electrode at the first gate conductive layer, spaced from the first capacitor electrode, overlapping the first electrode portion of the sixth transistor, and electrically connected to the first power line; and a third capacitor electrode at the second gate conductive layer, overlapping the first capacitor electrode and the second capacitor electrode, and electrically connected to the second electrode portion of the first transistor and the first electrode portion of the sixth transistor. The gate electrode of the first transistor is at the third gate conductive layer. The first capacitor is formed in an overlapping area between the first capacitor electrode and the third capacitor electrode. The second capacitor is formed in an overlapping area between the second capacitor electrode and the third capacitor electrode.

Each of at least some of the light emitting pixel drivers further includes a fourth capacitor electrode located at the light blocking conductive layer, overlapping the second capacitor electrode, and electrically connected to the first power line. The second capacitor is further located in an overlapping area between one of the first electrode portion of the sixth transistor and the second capacitor electrode and the fourth capacitor electrode.

The emission areas include a first emission area configured to emit light of a first wavelength band; a second emission area configured to emit light of a second wavelength band lower than the first wavelength band; and a third emission area configured to emit light of a third wavelength band lower than the second wavelength band. The light emitting pixel drivers include a first light emitting pixel driver electrically connected to a light emitting element of the first emission area; a second light emitting pixel driver electrically connected to a light emitting element of the second emission area; and a third light emitting pixel driver electrically connected to a light emitting element of the third emission area. The fourth capacitor electrode of the first light emitting pixel driver from among the at least some of the light emitting pixel drivers has a first width. The fourth capacitor electrode of the third light emitting pixel driver from among the at least some of the light emitting pixel drivers has a second width smaller than the first width. The fourth capacitor electrode of the second light emitting pixel driver from among the at least some of the light emitting pixel drivers has a third width smaller than the second width.

The display area includes a main display area where the emission areas are arranged side by side with each other; and at least one sub-display area surrounded by the main display area. The at least one sub-display area includes the emission areas and light transmitting areas located between the emission areas. At least some of the light emitting pixel drivers are electrically connected to light emitting elements in the emission areas of the at least one sub-display area.

The circuit layer further includes a first source-drain conductive layer on the second interlayer insulating layer; a first planarization layer covering the first source-drain conductive layer; a second source-drain conductive layer on the first planarization layer; and a second planarization layer covering the second source-drain conductive layer. The first power line includes a power sub-line at the first gate conductive layer and extending in a first direction; and a power main line at the second source-drain conductive layer and extending in a second direction crossing the first direction. The second capacitor electrode is a portion of the power sub-line. The power main line is electrically connected to the power sub-line and the fourth capacitor electrode through a power connection electrode at the first source-drain conductive layer.

The channel portion of the first transistor overlaps the first capacitor electrode, the third capacitor electrode, and the gate electrode of the first transistor.

The circuit layer further includes a bias voltage line at the light blocking conductive layer and configured to transmit a bias voltage; a reset control line at the third gate conductive layer and configured to transmit a reset control signal; and an initialization control line at the third gate conductive layer and configured to transmit an initialization control signal. A gate electrode of the third transistor is electrically connected to the reset control line. A gate electrode of the fourth transistor is electrically connected to the initialization control line. In each of at least some of the light emitting pixel drivers. The channel portion of the third transistor overlaps the gate electrode of the third transistor and a portion of the reset control line. The channel portion of the fourth transistor overlaps the gate electrode of the fourth transistor and another portion of the bias voltage line.

The display area includes a main display area where the emission areas are arranged side by side with each other; and at least one sub-display area surrounded by the main display area. The at least one sub-display area includes the emission areas and light transmitting areas located between the emission areas. At least some of the light emitting pixel drivers are electrically connected to light emitting elements in the emission areas of the at least one sub-display area.

The circuit layer further includes a bias voltage line at the light blocking conductive layer and configured to transmit a bias voltage; a first emission control line at the first gate conductive layer and configured to transmit a first emission control signal; and a second emission control line at the first gate conductive layer and configured to transmit a second emission control signal. A gate electrode of the fifth transistor is electrically connected to the first emission control line. A gate electrode of the sixth transistor is electrically connected to the second emission control line. In each of at least some of the light emitting pixel drivers. The channel portion of the fifth transistor overlaps the gate electrode of the fifth transistor and a portion of the bias voltage line. The channel portion of the sixth transistor overlaps the gate electrode of the sixth transistor and another portion of the bias voltage line.

The display area includes a main display area where the emission areas are arranged side by side with each other; and at least one sub-display area surrounded by the main display area. The at least one sub-display area includes the emission areas and light transmitting areas located between the emission areas. At least some of the light emitting pixel drivers are electrically connected to light emitting elements in the emission areas of the at least one sub-display area.

According to one or more embodiments of the present disclosure, there is provided an electronic device including a display device configured to display an image; a memory configured to store an application; a processor configured to execute the application and configured to transmit an image data signal and an input control signal to the display device; and a power module configured to transmit power to the display device. The display device includes a substrate including a display area where emission areas are arranged; a circuit layer on the substrate; and an element layer on the circuit layer. The circuit layer includes a light blocking conductive layer on the substrate; a buffer layer covering the light blocking conductive layer; a first semiconductor layer on the buffer layer; a first interlayer insulating layer on the first semiconductor layer; and a second semiconductor layer on the first interlayer insulating layer and including an oxide semiconductor material.

The element layer includes light emitting elements in the emission areas. The circuit layer includes light emitting pixel drivers configured to respectively transmit driving currents to the light emitting elements; and a bias voltage line at the light blocking conductive layer and configured to transmit a bias voltage. Each of the light emitting pixel drivers includes a first transistor configured to generate the driving current. The first transistor includes a gate electrode, a channel portion overlapping the gate electrode, a first electrode portion connected to one side of the channel portion, and a second electrode portion connected to an other side of the channel portion. The channel portion, the first electrode portion, and the second electrode portion of the first transistor are at the second semiconductor layer.

Each of the light emitting pixel drivers further includes a second transistor electrically connected between a data line configured to transmit a data signal and the gate electrode of the first transistor; a third transistor electrically connected between a reference voltage line configured to transmit a reference voltage and the gate electrode of the first transistor; a fourth transistor electrically connected between an initialization voltage line configured to transmit an initialization voltage and one of the light emitting elements; a fifth transistor electrically connected between a first power line configured to transmit a first power and the first electrode portion of the first transistor; a sixth transistor electrically connected between the one of the light emitting elements and the second electrode portion of the first transistor; a first capacitor electrically connected between the gate electrode of the first transistor and the second electrode portion of the first transistor; and a second capacitor electrically connected between the first power line configured to transmit the first power and the second electrode portion of the first transistor. The circuit layer further includes a first gate insulating layer covering the first semiconductor layer; a first gate conductive layer on the first gate insulating layer; a second gate insulating layer covering the first gate conductive layer; a second gate conductive layer between the second gate insulating layer and the first interlayer insulating layer; a third gate insulating layer covering the second semiconductor layer; and a third gate conductive layer between the third gate insulating layer and the second interlayer insulating layer. Each of the light emitting pixel drivers further include a first capacitor electrode at the first gate conductive layer and electrically connected to the gate electrode of the first transistor; a second capacitor electrode at the first gate conductive layer, spaced apart from the first capacitor electrode, overlapping the first electrode portion of the sixth transistor, and electrically connected to the first power line; and a third capacitor electrode at the second gate conductive layer, overlapping the first capacitor electrode and the second capacitor electrode, and electrically connected to the second electrode portion of the first transistor and the first electrode portion of the sixth transistor. The gate electrode of the first transistor is at the third gate conductive layer. The first capacitor is in an overlapping area between the first capacitor electrode and the third capacitor electrode. The second capacitor is in an overlapping area between the second capacitor electrode and the third capacitor electrode.

Each of at least some of the light emitting pixel drivers further includes a fourth capacitor electrode at the light blocking conductive layer, overlapping the second capacitor electrode, and electrically connected to the first power line. The second capacitor is further located in an overlapping area between one of the first electrode portion of the sixth transistor and the second capacitor electrode and the fourth capacitor electrode.

The emission areas include a first emission area configured to emit light of a first wavelength band; a second emission area configured to emit light of a second wavelength band lower than the first wavelength band; and a third emission area configured to emit light of a third wavelength band lower than the second wavelength band. The light emitting pixel drivers include a first light emitting pixel driver electrically connected to a light emitting element of the first emission area; a second light emitting pixel driver electrically connected to a light emitting element of the second emission area; and a third light emitting pixel driver electrically connected to a light emitting element of the third emission area. A fourth capacitor electrode of the first light emitting pixel driver of the at least some of the light emitting pixel drivers has a first width. A fourth capacitor electrode of the third light emitting pixel driver of the at least some of the light emitting pixel drivers has a second width smaller than the first width. A fourth capacitor electrode of the second light emitting pixel driver of the at least some of the light emitting pixel drivers has a third width smaller than the second width.

The circuit layer further includes a reset control line at the third gate conductive layer and configured to transmit a reset control signal; and an initialization control line at the third gate conductive layer and configured to transmit an initialization control signal. A channel portion, a first electrode portion, and a second electrode portion of each of the third transistor and the fourth transistor are at the second semiconductor layer. A gate electrode of the third transistor is electrically connected to the reset control line. A gate electrode of the fourth transistor is electrically connected to the initialization control line. In each of at least some of the light emitting pixel drivers. The channel portion of the third transistor overlaps the gate electrode of the third transistor and a portion of the reset control line. The channel portion of the fourth transistor overlaps the gate electrode of the fourth transistor and another portion of the bias voltage line.

The circuit layer further includes a first emission control line at the first gate conductive layer and configured to transmit a first emission control signal; and a second emission control line at the first gate conductive layer and configured to transmit a second emission control signal. A channel portion, a first electrode portion, and a second electrode portion of each of the fifth transistor and the sixth transistor are at the first semiconductor layer. A gate electrode of the fifth transistor is electrically connected to the first emission control line. A gate electrode of the sixth transistor is electrically connected to the second emission control line. In each of at least some of the light emitting pixel drivers. The channel portion of the fifth transistor overlaps the gate electrode of the fifth transistor and a portion of the bias voltage line. The channel portion of the sixth transistor overlaps the gate electrode of the sixth transistor and another portion of the bias voltage line.

A circuit layer of a display device according to one or more embodiments may include a light blocking conductive layer on a substrate, a buffer layer covering the light blocking conductive layer, a first semiconductor layer on the buffer layer, a first interlayer insulating layer on the first semiconductor layer, and a second semiconductor layer on the first interlayer insulating layer and including an oxide semiconductor material.

The circuit layer may include light emitting pixel drivers configured to respectively transmit driving currents to light emitting elements of an element layer, and each of the light emitting pixel drivers may include a first transistor generating the driving current. A channel portion of the first transistor may be at the second semiconductor layer.

Each of the light emitting pixel drivers may include a second transistor electrically connected between a data line and a gate electrode of the first transistor, a third transistor electrically connected between a reference voltage line and the gate electrode of the first transistor, a fourth transistor electrically connected between an initialization voltage line and one light emitting element, a fifth transistor electrically connected between a first power line and a first electrode portion of the first transistor, a sixth transistor electrically connected between a second electrode portion of the first transistor and one light emitting element, a first capacitor electrically connected between the gate electrode of the first transistor and the second electrode portion of the first transistor, and a second capacitor electrically connected between the first power line and the second electrode portion of the first transistor.

Each of the light emitting pixel drivers may include a first capacitor electrode and a second capacitor electrode at a first gate conductive layer and a third capacitor electrode at a second gate conductive layer. The first capacitor electrode may be electrically connected to the gate electrode of the first transistor, the second capacitor electrode may be electrically connected to the first power line, and the third capacitor electrode may overlap the first capacitor electrode and the second capacitor electrode and may be electrically connected to the second electrode portion of the first transistor.

Accordingly, the first capacitor may be formed in an overlapping area between the first capacitor electrode and the third capacitor electrode.

In addition, the second capacitor may be formed in an overlapping area between the second capacitor electrode and the third capacitor electrode.

According to one or more embodiments, each of at least some of the light emitting pixel drivers of the light emitting pixel drivers may further include a fourth capacitor electrode at the light blocking conductive layer, overlapping the second capacitor electrode, and electrically connected to the first power line.

Accordingly, the second capacitor may be formed in an overlapping area between the second capacitor electrode and the fourth capacitor electrode.

Alternatively, when a first electrode portion of the sixth transistor extends to overlap the second capacitor electrode, the second capacitor may be further formed in an overlapping area between the first electrode portion of the sixth transistor and the fourth capacitor electrode.

That is, the second capacitor may be further formed in an overlapping area between one of the first electrode portion of the sixth transistor and the second capacitor electrode and the fourth capacitor electrode.

Because the fourth capacitor electrode is at the light blocking conductive layer different from layers at which the second capacitor electrode and the third capacitor electrode are located, even though a width of the overlapping area between the second capacitor electrode and the third capacitor electrode is maintained as it is, capacitance of the second capacitor may be increased by the fourth capacitor electrode.

In other words, luminance of light emitting elements electrically connected to at least some of the light emitting pixel drivers may be increased without increasing a width of each of at least some of the light emitting pixel drivers.

Accordingly, in one or more embodiments, luminance and a resolution of the display device and an electronic device including the same may be improved together.

The effects, aspects, and features of embodiments of the present disclosure are not limited to the aforementioned effects, aspects, and features and various other effects aspects, and features are included in the present specification.

### BRIEF DESCRIPTION OF THE DRAWINGS

The above and other aspects and features of embodiments of the present disclosure will become more apparent by describing in detail embodiments thereof with reference to the attached drawings, in which:

FIG. 1 is a perspective view illustrating an electronic device according to one or more embodiments;

FIG. 2 is an exploded perspective view of the electronic device illustrated in FIG. 1;

FIG. 3 is a plan view illustrating a display device of FIG. 2;

FIG. 4 is a cross-sectional view taken along the line A-A′ of FIG. 3;

FIG. 5 is a schematic view illustrating a portion B of FIG. 3;

FIG. 6 is a cross-sectional view taken along the line D-D′ of FIG. 5;

FIG. 7 is a schematic view illustrating a portion C of FIG. 3;

FIG. 8 is a cross-sectional view taken along the line E-E′ of FIG. 7;

FIG. 9 is a block diagram illustrating the display device of FIG. 2;

FIG. 10 is an equivalent circuit diagram illustrating a main light emitting pixel driver of FIG. 5 according to one or more embodiments;

FIG. 11 is a cross-sectional view illustrating a first transistor, a second transistor, a sixth transistor, a first capacitor, a second capacitor, and a light emitting element of FIG. 10;

FIGS. 12-14 are equivalent circuit diagrams illustrating a sub-light emitting pixel driver of FIG. 7 according to one or more of embodiments;

FIG. 15 is a plan view illustrating the sub-light emitting pixel driver according to an embodiment of FIG. 14;

FIG. 16 is a cross-sectional view illustrating a third transistor according to an embodiment of FIG. 12 and the embodiment of FIG. 14;

FIG. 17 is a cross-sectional view illustrating a fourth transistor according to the embodiment of FIG. 12 and the embodiment of FIG. 14;

FIG. 18 is a cross-sectional view illustrating a fifth transistor according to an embodiment of FIG. 13 and the embodiment of FIG. 14;

FIG. 19 is a cross-sectional view illustrating a sixth transistor according to the embodiment of FIG. 13 and the embodiment of FIG. 14;

FIGS. 20-24 are plan views illustrating two adjacent sub-light emitting pixel drivers according to one or more embodiments;

FIG. 25 is a cross-sectional view taken along the line F-F′ of FIG. 24;

FIG. 26 is a cross-sectional view taken along the line G-G′ of FIG. 24;

FIGS. 27 and 28 are plan views illustrating a fourth capacitor electrode according to one or more of embodiments;

FIG. 29 is a block diagram of an electronic device according to one or more embodiments; and

FIG. 30 is schematic views of electronic devices according to various embodiments.

### DETAILED DESCRIPTION

Embodiments will now be described more fully hereinafter with reference to the accompanying drawings. The embodiments may, however, be provided in different forms and should not be construed as limiting. The same reference numbers indicate the same components throughout the present disclosure. In the accompanying figures, the thickness of layers and regions may be exaggerated for clarity.

Some of the parts which are not associated with the description may not be provided in order to describe embodiments of the present disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” and/or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” and/or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which the present disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, embodiments will be described with reference to the accompanying drawings.

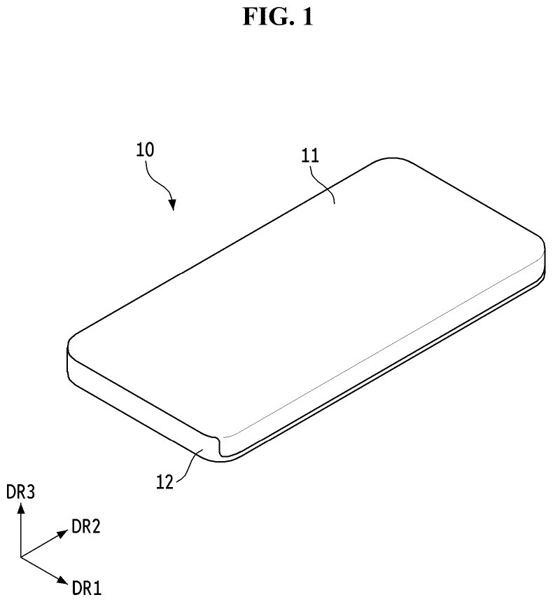

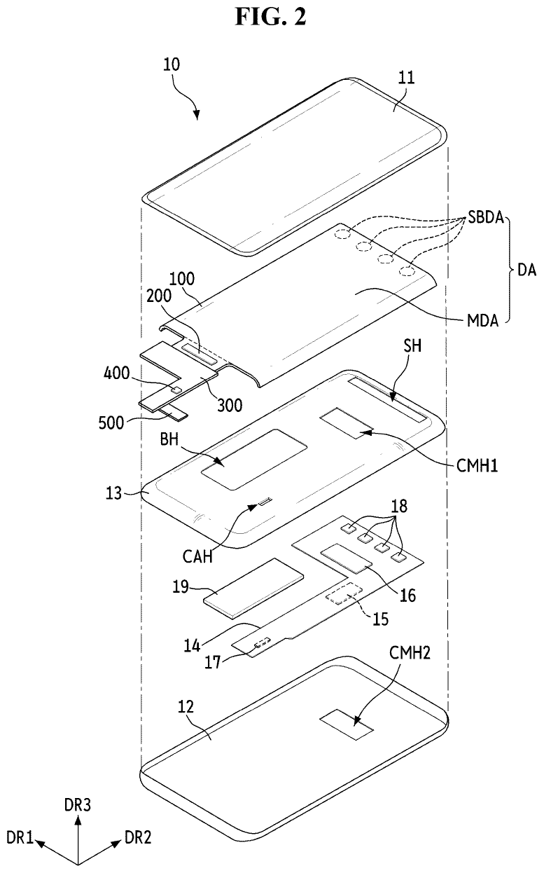

FIG. 1 is a perspective view illustrating an electronic device according to one or more embodiments. FIG. 2 is an exploded perspective view of the electronic device illustrated in FIG. 1.

Referring to FIG. 1, an electronic device 10 according to one or more embodiments is an apparatus having a function of displaying an image on a display area. The electronic device 10 may provide portability. As an example, the electronic device 10 may be a portable electronic device such as a mobile phone, a smartphone, a tablet personal computer (PC), a smart watch, a watch phone, a mobile communication terminal, an electronic notebook, an electronic book, a portable multimedia player (PMP), a navigation device, or an ultra-mobile personal computer (UMPC).

The electronic device 10 according to one or more embodiments is not limited to the portable electronic device, and may also be a large apparatus such as a television, a laptop computer, a monitor, a billboard, and/or the Internet of Thing (IOT).

The electronic device 10 may have a shape similar to a rectangular shape in a plan view. For example, the electronic device 10 may have a rectangular shape, in a plan view, having short sides in a first direction DR1 and long sides in a second direction DR2 crossing the first direction DR1. A corner where the short side in the first direction DR1 and the long side in the second direction DR2 meet may be rounded with a selected curvature or right-angled. The shape of the electronic device 10 in a plan view is not limited to the rectangular shape, and may be other polygonal shapes, a circular shape, or an elliptical shape.

The first direction DR1 as used herein may be a direction parallel to the short side of the electronic device 10, that is, a transverse direction of the electronic device 10, in a plan view. The second direction DR2 as used herein may be a direction parallel to the long side of the electronic device 10, that is, a longitudinal direction of the electronic device 10, in a plan view. A third direction DR3 as used herein may be a thickness direction of the electronic device 10.

The electronic device 10 according to one or more embodiments may include a display device 100 (see FIG. 2) and a cover window 11 and a lower cover 12 that are provided as a housing protecting the display device.

Referring to FIG. 2, the electronic device 10 may further include a display device 100, a bracket 13, and a main circuit board 14 housed between the cover window 11 and the lower cover 12.

The electronic device 10 may include a display surface in which a display area DA implementing an image display is disposed.

The display device 100 may include a display area DA for emitting light to the display surface of the electronic device 10.

The display area DA may include a main display area MDA disposed over most of the display area DA and at least one sub-display area SBDA surrounded by the main display area MDA.

At least one sub-display area SBDA may overlap at least one optical device 18.

The cover window 11 may be disposed above the display device 100 so as to cover an upper surface of the display device 100. The cover window 11 may serve to protect the upper surface of the display device 100.

The cover window 11 may include a light transmitting portion that is transparent and a light blocking portion that is opaque.

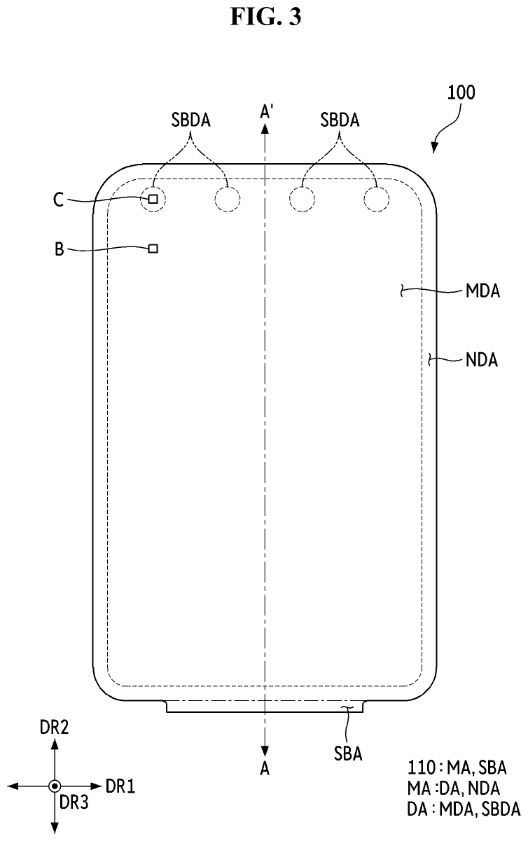

The light transmitting portion of the cover window 11 may overlap the display area DA of the display device 100 in the third direction DR3, and the light blocking portion of the cover window 11 may overlap a non-display area NDA (see FIG. 3) of the display device 100 in the third direction DR3.

The cover window 11 may include an upper surface portion forming an upper surface of the electronic device 10, a left surface portion forming a left surface of the electronic device 10, and a right surface portion forming a right surface of the electronic device 10. The left surface portion of the cover window 11 may extend from the left side of the upper surface portion, and the right surface portion of the cover window 11 may extend from the right side of the upper surface portion.

Each of the upper surface portion, the left surface portion, and the right surface portion of the cover window 11 may include a light transmitting portion and a light blocking portion.

The light transmitting portion of the cover window 11 may be disposed over most of each of the upper surface portion, the left surface portion, and the right surface portion of the cover window 11.

The light blocking portion of the cover window 11 may be disposed at an upper edge and a lower edge of the upper surface portion of the cover window 11, an upper edge, a left edge, and a lower edge of the left surface portion of the cover window 11, and an upper edge, a right edge, and a lower edge of the right surface portion of the cover window 11.

The display device 100 may include an upper surface portion facing the upper surface portion of the cover window 11, a left surface portion facing the left surface portion of the cover window 11, and a right surface portion facing the right surface portion of the cover window 11. The left surface portion of the display device 100 may extend from the left side of the upper surface portion, and the right surface portion of the display device 100 may extend from the right side of the upper surface portion.

The display device 100 may include a display area DA for displaying an image.

Each of the upper surface portion, the left surface portion, and the right surface portion of the display device 100 may include a display area DA.

The display area DA may be disposed over most of each of the upper surface portion, the left surface portion, and the right surface portion of the display device 100.

The display device 100 may further include a display driving circuit 200, a display circuit board 300, a touch driving circuit 400, and a cable 500 extending from one side of the display circuit board 300.

The bracket 13 may be disposed below the display device 100.

The bracket 13 may include plastic, metal, or both plastic and metal. The bracket 13 may include a first camera hole CMH1 into which a camera device 16 is inserted, a battery hole BH fixing a battery 19, a light transmitting hole SH into which at least one optical device 18 is inserted, and a cable hole CAH, which is a passage of the cable 500 connected to the display circuit board 300.

The main circuit board 14 and the battery 19 may be disposed below the bracket 13. The main circuit board 14 may be a printed circuit board (PCB) or a flexible printed circuit board (FPCB).

A main processor 15, the camera device 16, a main connector 17, and at least one optical device 18 may be mounted on the main circuit board 14.

The camera device 16 may be disposed on both upper and lower surfaces of the main circuit board 14, the main processor 15 may be disposed on the upper surface of the main circuit board 14, and the main connector 17 may be disposed on the upper surface of the main circuit board 14.

The main processor 15 may control all functions of the electronic device 10.

For example, the main processor 15 may output digital video data to the display driving circuit 200 through the display circuit board 300 so that the display device 100 displays the image. In addition, the main processor 15 may receive touch data including a touch coordinates of a user from the touch driving circuit 400, decide whether or not the user has performed a touch or whether or not the user has performed approach, and then execute an operation corresponding to a touch input or an approach input of the user. For example, the main processor 15 may execute an application or perform an operation indicated by an icon touched by the user.

The main processor 15 may be an application processor, a central processing unit (CPU), or a system chip formed as an integrated circuit (IC).

The camera device 16 processes an image frame such as a still image and/or a moving image obtained by an image sensor in a camera mode and outputs the processed image frame to the main processor 15.

The cable 500 passing through the cable hole CAH of the bracket 13 may be connected to the main connector 17. For this reason, the main circuit board 14 may be electrically connected to the display circuit board 300.

At least one optical device 18 may include a proximity sensor, an illuminance sensor, an iris sensor, and/or a second camera sensor.

The proximity sensor, the illuminance sensor, the iris sensor, and/or the second camera sensor may be disposed on the upper surface of the main circuit board 14 and disposed in the light emitting hole SH of the bracket 13.

The proximity sensor is a sensor for sensing an object approaching a front surface of the electronic device 10. The proximity sensor may include a light source outputting light and a light receiving portion receiving light reflected by the object. The proximity sensor may generate a sensing signal corresponding to an amount of light reflected by the object, and it may be decided by the sensing signal of the proximity sensor whether or not there is an object located close to the front surface of the electronic device 10.

The illuminance sensor is a sensor for sensing brightness of the front surface of the electronic device 10. The illuminance sensor may include a resistor whose resistance value changes depending on brightness of incident light.

The iris sensor is a sensor for capturing an image of a user's iris. It may be verified whether or not the user is a pre-registered user according to whether or not the image captured by the iris sensor is the same as an iris image pre-stored in a memory.

The second camera sensor processes an image frame such as a still image and/or a moving image obtained by an image sensor and outputs the processed image frame to the main processor 15. The second camera sensor may be a complementary metal oxide semiconductor (CMOS) image sensor or a charge coupled device (CCD) image sensor. The number of pixels of the second camera sensor may be smaller than the number of pixels of the camera device 16, and a size of the second camera sensor may be smaller than a size of the camera device 16.

The battery 19 may be spaced (e.g., spaced apart) from the main circuit board 14. That is, the battery 19 may not overlap the main circuit board 14 in the third direction DR3. The battery 19 may be disposed in the battery hole BH of the bracket 13 in the third direction DR3.

In addition, a mobile communication module capable of transmitting and receiving wireless signals to and from at least one of a base station, an external terminal, and a server over a mobile communication network may be further mounted on the main circuit board 14. The wireless signal may include various types of data according to transmission/reception of a voice signal, a video call signal, and/or a text/multimedia message.

The lower cover 12 may be disposed below the main circuit board 14 and the battery 19. The lower cover 12 may be fastened and fixed to the bracket 13. The lower cover 12 may form an upper side surface, a lower side surface, and a lower surface of the electronic device 10. The lower cover 12 may include plastic, metal, or both plastic and metal.

The lower cover 12 may include a second camera hole CMH2 through which a lower surface of the camera device 16 is exposed.

However, locations of the light emitting hole SH, the first camera hole CMH1, and the second camera hole CMH2 are not limited to those illustrated in FIG. 2.

Next, display devices 100 according to one or more embodiments will be described.

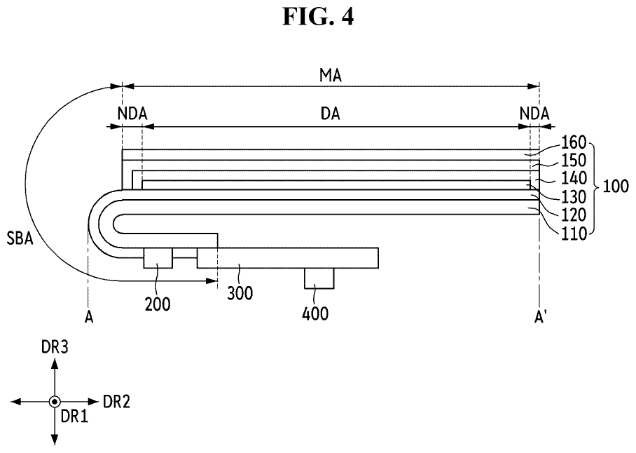

FIG. 3 is a plan view illustrating a display device of FIG. 2. FIG. 4 is a cross-sectional view taken along the line A-A′ of FIG. 3.

Referring to FIGS. 3 and 4, the display device 100 according to one or more embodiments may be a light emitting display device such as an organic light emitting display device using organic light emitting diodes (OLEDs), a quantum dot light emitting display device including quantum dot light emitting layers, an inorganic light emitting display device including inorganic semiconductors, and/or a micro light emitting display device using micro or nano light emitting diodes (micro LEDs or nano LEDs). Hereinafter, it will be mainly described that the display device 100 is an organic light emitting display device. However, the present disclosure is not limited thereto, and may be applied to a display device including an organic insulating material, an organic light emitting material, and/or a metal material.

The display device 100 may be formed to be flat, but is not limited thereto. For example, the display device 100 may include curved surface portions formed at left and right ends thereof and having a constant curvature or a variable curvature. In addition, the display device 100 may be flexibly formed to be curved, bent, folded, and/or rolled.

Referring to FIG. 3, at least one surface of the display device 100 includes a main area MA from which light for displaying an image is emitted.

The display area DA may be formed in a rectangular shape, in a plan view, having short sides in the first direction DR1 and long sides in the second direction DR2 crossing the first direction DR1. A corner where the short side in the first direction DR1 and the long side in the second direction DR2 meet may be rounded with a selected curvature or right-angled. A shape of the display area DA in a plan view is not limited to the rectangular shape, and may be other polygonal shapes, a circular shape, or an elliptical shape.

The display area DA may be disposed over most of the main area MA. The display area DA may be disposed at the center of the main area MA.

The display area DA may include a main display area MDA disposed over most of the display area DA and at least one sub-display area SBDA surrounded by the main display area MDA.

At least one sub-display area SBDA may overlap at least one optical device 18 (see FIG. 2).

The non-display area NDA may be disposed around the display area DA along an edge or a periphery of the display area DA. That is, the main display area MDA may be surrounded by the non-display area NDA.

The display device 100 may include a substrate 110 including the main area MA and a sub-area SBA.

Referring to FIG. 4, the sub-area SBA may protrude from at least a portion of one side of the main area MA in the second direction DR2.

A portion of the sub-area SBA is transformed into a bent shape, such that another portion of the sub-area SBA may be disposed on a rear surface of the display device 100.

According to one or more embodiments, the display device 100 includes a substrate 110, a circuit layer 120 disposed on the substrate 110, and an element layer 130 disposed on the circuit layer 120.

The display device 100 may further include a sealing layer 140 disposed on the element layer 130 and a touch sensor layer 150 disposed on the sealing layer 140.

The display device 100 may further include a polarizing layer 160 disposed on the touch sensor layer 150 in order to reduce external light reflection.

The substrate 110 may include a main area MA corresponding to the display surface and a sub-area SBA protruding from at least a portion of one side of the main area MA.

The main area MA may include a display area DA from which light is emitted and a non-display area NDA disposed around the display area DA.

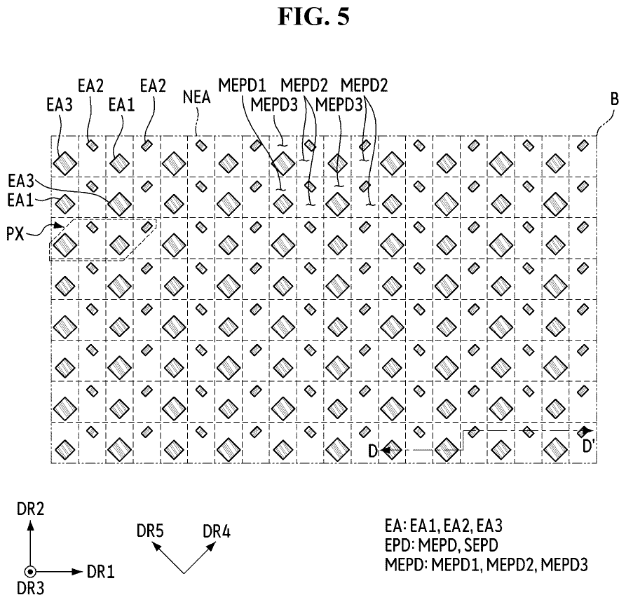

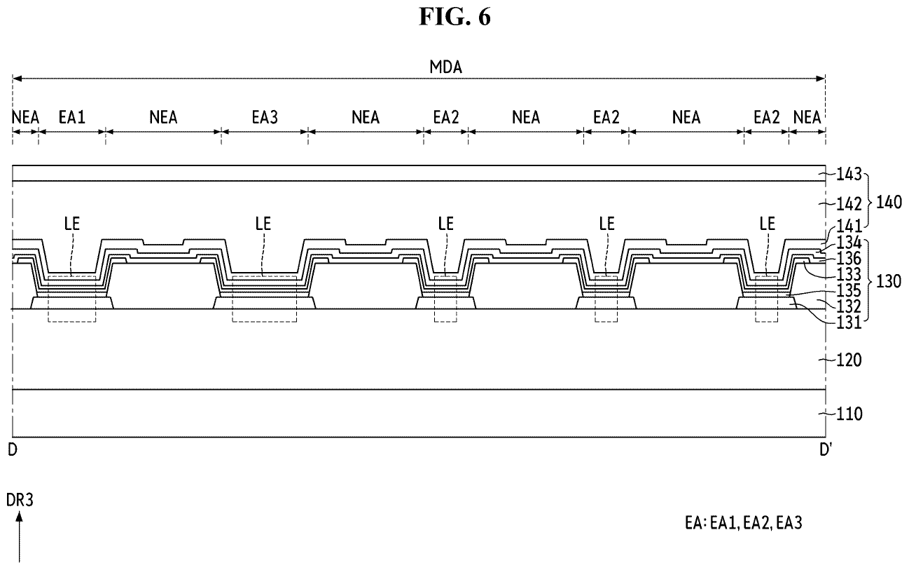

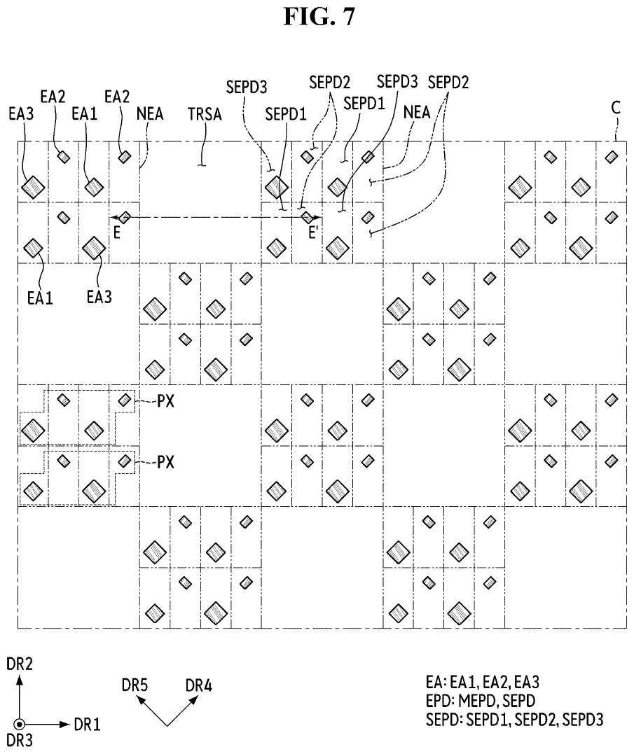

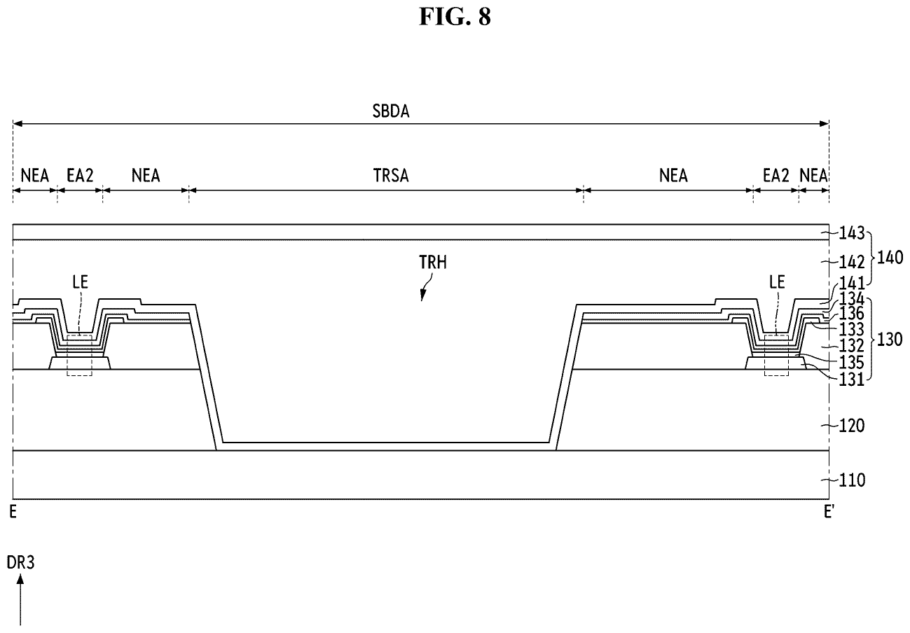

The element layer 130 may include light emitting elements LE (see FIGS. 6 and 8) respectively disposed in emission areas EA (see FIGS. 5 and 7).

The circuit layer 120 may include light emitting pixel drivers EPD (see FIGS. 5 and 7) electrically connected to the light emitting elements LE.

The sealing layer 140 may cover the element layer 130. The sealing layer 140 may include a structure in which two or more inorganic films and at least one organic film are alternately stacked.

The touch sensor layer 150 may be disposed on the sealing layer 140, and may correspond to the main area MA. The touch sensor layer 150 may include touch electrodes for sensing a touch of a person or an object.

The polarizing layer 160 is used to prevent deterioration of visibility of an image due to external light reflection by blocking external light reflected from the touch sensor layer 150, the sealing layer 140, the element layer 130, and the circuit layer 120 and interfaces between these layers.

As a portion of the sub-area SBA is transformed into the bent shape, the display driving circuit 200 mounted on the sub-area SBA and the display circuit board 300 connected to one side of the sub-area SBA may be disposed under the substrate 110.

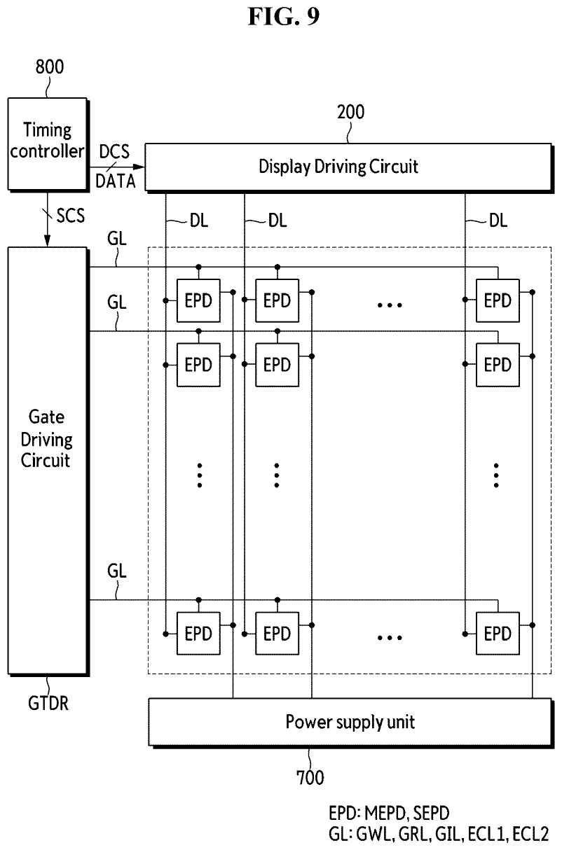

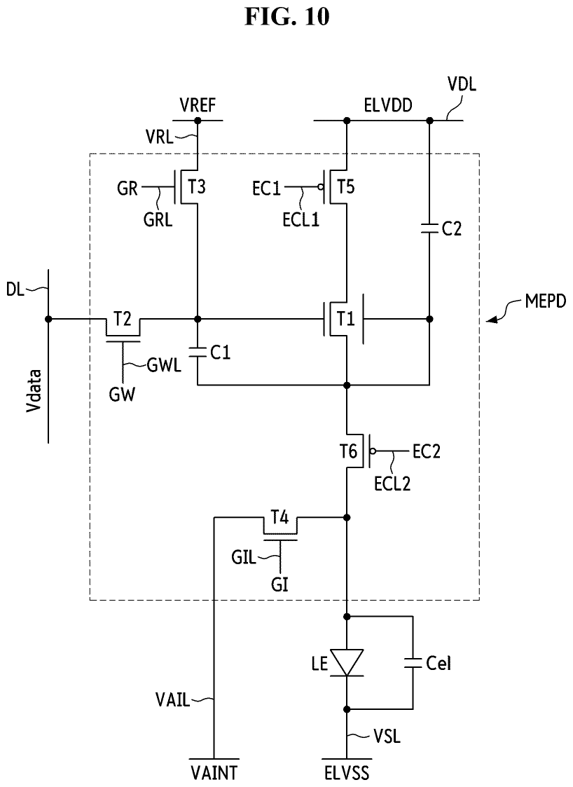

The display driving circuit 200 may be electrically connected to data lines DL (see FIG. 9) of the circuit layer 120. The display driving circuit 200 may transmit data signals Vdata (see FIG. 10) of light emitting pixel drivers EPD (see FIGS. 5 and 7) to the data lines DL based on control signals, power, and voltages supplied from the display circuit board 300.

The display driving circuit 200 may be provided as an integrated circuit (IC) and mounted on the sub-area SBA of the display device 100 in a chip on glass (COG) manner, a chip on plastic (COP) manner, and/or an ultrasonic manner. However, this is only an example, and the present disclosure is not limited thereto. For example, the display driving circuit 200 may also be mounted on the display circuit board 300.

One end of the display circuit board 300 may be attached onto pads disposed at an edge of one side of the sub-area SBA of the display device 100 using an anisotropic conductive film.

The display circuit board 300 may be a flexible printed circuit board (FPCB) that may be bent, a rigid printed circuit board (PCB) that maintains a flat shape, or a composite printed circuit board (PCB) that includes both a rigid printed circuit board and a flexible printed circuit board.

The display circuit board 300 may be connected to signal pads disposed on one side of the sub-area SBA.

The touch driving circuit 400 may be mounted on the display circuit board 300.

The touch driving circuit 400 may be electrically connected to the touch sensor layer 150.

The touch driving circuit 400 may apply touch driving signals to driving lines of the touch sensor layer 150 and may receive touch sensing signals from sensing lines. In addition, the touch driving circuit 400 may decide whether or not the user has performed a touch, whether or not the user has performed approach, and/or the like, by sensing charge change amounts of capacitance based on the touch sensing signals.

The touch of the user indicates that a user's finger and/or an object such as a pen comes into direct contact with an upper surface of the cover window disposed on the touch sensor layer. The approach of the user indicates that the user's finger and/or the object such as the pen hovers above the upper surface of the cover window.

The touch driving circuit 400 may output touch data including a touch coordinates of the user to the main processor 15 (see FIG. 2).

FIG. 5 is a schematic view illustrating a portion B of FIG. 3. FIG. 6 is a cross-sectional view taken along the line D-D′ of FIG. 5.

FIG. 5 is a schematic view illustrating the main display area MDA (see FIG. 3) in the display area DA (see FIG. 3).

As illustrated in FIG. 5, the main display area MDA in the display area DA may include emission areas EA arranged side by side with each other.

The main display area MDA does not emit light in a non-emission area NEA, which is an area between the emission areas EA spaced (e.g., spaced apart) from each other.

Light for displaying an image may be emitted through the emission areas EA.

Each of the emission areas EA may be a unit area for emitting light of a wavelength band corresponding to one of two or more different colors with luminance corresponding to an image signal.

Each of the emission areas EA may be disposed in a quadrangular shape.

However, this is only an example, and a shape of each of the emission areas EA according to one or more embodiments in a plan view is not limited to that illustrated in FIG. 5. That is, each of the emission areas EA may have a polygonal shape such as a rectangular shape, a square shape, a hexagonal shape, and/or an octagonal shape other than a rhombic shape, a circular shape, or an elliptical shape, in a plan view.

The emission areas EA may include first emission areas EA1 for emitting light of a first wavelength band, second emission areas EA2 for emitting light of a second wavelength band lower than the first wavelength band, and third emission areas EA3 for emitting light of a third a wavelength band lower than the second wavelength band.

As an example, the first wavelength band may be about 600 nm to about 750 nm, and may correspond to red. The second wavelength band may be about 480 nm to about 560 nm, and may correspond to green. The third wavelength band may be about 370 nm to about 460 nm, and may correspond to blue.

However, this is only an example, and the first wavelength band, the second wavelength band, and the third wavelength band according to one or more embodiments are not limited thereto.

As the emission areas EA include the first emission areas EA1, the second emission areas EA2, and the third emission areas EA3, unit pixels PX may be respectively provided by combinations of one or more first emission areas EA1, one or more second emission areas EA2, and one or more third emission areas EA3 adjacent to each other from among the emission areas EA.

Each of the unit pixels PX may be a unit for displaying various colors including white. That is, light of various colors displayed by each unit pixel PX may be implemented by color mixing of light emitted from two or more emission areas EA included in each unit pixel PX with each other.

The third emission area EA3 may have a greater width than the first emission area EA1, and the first emission area EA1 may have a greater width than the second emission area EA2. However, this is only an example, and a width of each of the emission areas EA is not limited to that illustrated in FIG. 5.

The first emission areas EA1 and the third emission areas EA3 may be alternately arranged along the second direction DR2.

The second emission areas EA2 may be arranged side by side along the second direction DR2.

Each of the second emission areas EA2 may neighbor to the first emission area EA1 or the third emission area EA3 in diagonal directions DR4 and DR5 crossing the first direction DR1 and the second direction DR2.

In this case, each of the unit pixels PX may include one first emission area EA1 and one third emission area EA3 neighboring to each other in the second direction DR1 and two second emission areas EA2 neighboring to one first emission area EA1 and one third emission area EA3 in the diagonal directions DR4 and DR5. However, this is only an example, and an arrangement form of the emission areas EA according to one or more embodiments and components of the unit pixel PX are not limited to those described above.

According to one or more embodiments, the element layer 130 (see FIG. 4) may include light emitting elements LE (see FIG. 6) disposed in the emission areas EA.

According to one or more embodiments, the circuit layer 120 (see FIG. 4) may include main light emitting pixel drivers MEPD arranged along the first direction DR1 and the second direction DR2 in the main display area MDA (see FIG. 3).

The main light emitting pixel drivers MEPD may be electrically connected respectively to light emitting elements LE (see FIG. 6) of the element layers 130 (see FIG. 4) disposed in the emission areas EA of the main display area MDA (see FIG. 3).

The main light emitting pixel drivers MEPD may include a first main light emitting pixel driver MEPD1 electrically connected to a light emitting element LE (see FIG. 6) disposed in the first emission area EA1 of the main display area MDA (see FIG. 3), a second main light emitting pixel driver MEPD2 electrically connected to a light emitting element LE (see FIG. 6) disposed in the second emission area EA2 of the main display area MDA (see FIG. 3), and a third main light emitting pixel driver MEPD3 electrically connected to a light emitting element LE (see FIG. 6) disposed in the third emission area EA3 of the main display area MDA (see FIG. 3).

The main light emitting pixel drivers MEPD may be arranged side by side with each other in the main display area MDA.

The first main light emitting pixel drivers MEPD1 and the third main light emitting pixel drivers MEPD3 may be alternately arranged along the second direction DR2.

The second main light emitting pixel drivers MEPD2 may be arranged side by side along the second direction DR2.

The second main light emitting pixel driver MEPD2 may be disposed between the first main light emitting pixel driver MEPD1 and the third main light emitting pixel driver MEPD3 in the first direction DR1.

Referring to FIG. 6, the element layer 130 may include light emitting elements LE respectively disposed in the emission areas EA of the main display area MDA.

The light emitting element LE may be an organic light emitting diode (OLED) including a light emitting layer made of an organic light emitting material. Alternatively, the light emitting element LE may be an inorganic light emitting element including a light emitting layer made of an inorganic semiconductor. Alternatively, the light emitting element LE may be a quantum dot light emitting element including a quantum dot light emitting layer. Alternatively, the light emitting element LE may be a micro light emitting diode.

Each of the light emitting elements LE may include an anode electrode 131 and a cathode electrode 134 facing each other and a light emitting layer 133 disposed between the anode electrode 131 and the cathode electrode 134.

That is, the element layer 130 may include anode electrodes 131 disposed in the emission areas EA of the main display area MDA, a pixel defining layer 132 disposed in the non-emission area NEA and covering edges of the anode electrodes 131, light emitting layers 133 disposed on the anode electrodes 131, and a cathode electrode 134 disposed on the light emitting layers 133 and the pixel defining layer 132.

Each of the light emitting elements LE may further include a first common layer 135 disposed between the anode electrode 131 and the light emitting layer 133 and a second common layer 136 disposed between the light emitting layer 133 and the cathode electrode 134.

The anode electrodes 131 of the main display area MDA (see FIG. 3) may be electrically connected to the main light emitting pixel drivers MEPD (see FIG. 5) of the circuit layer 120. Such an anode electrode 131 may be referred to as a pixel electrode.

The pixel defining layer 132 may include an organic insulating material.

The light emitting layers 133 may be disposed on the anode electrodes 131. Each of the light emitting layers 133 may be made of an organic light emitting material converting electron-hole pairs into light.

The cathode electrode 134 may be disposed on the light emitting layers 133 and the pixel defining layer 132. That is, the cathode electrode 134 may be entirely disposed in the main display area MDA. Such a cathode electrode 134 may be referred to as a common electrode.

The sealing layer 140 may be disposed on the element layer 130 and may cover the element layer 130.

The sealing layer 140 may include a first sealing layer 141 disposed on the element layer 130 and including an inorganic insulating material, a second sealing layer 142 disposed on the first sealing layer 141, overlapped with the element layer 130 and including an organic insulating material, and a third sealing layer 143 covering the second sealing layer 142 and including an inorganic insulating material.

FIG. 7 is a schematic view illustrating a portion C of FIG. 3. FIG. 8 is a cross-sectional view taken along the line E-E′ of FIG. 7.

FIG. 7 is a schematic view illustrating at least one sub-display area SBDA (see FIG. 3) in the display areas DA (see FIG. 3).

Referring to FIG. 7, at least one sub-display area SBDA (see FIG. 3) may include not only emission areas EA but also light transmitting areas TRSA disposed between the emission areas EA.

At least one sub-display area SBDA (see FIG. 3) may further include a non-emission area NEA disposed between the emission areas EA and the light transmitting areas TRSA.

The emission areas EA of at least one sub-display area SBDA (see FIG. 3) may have a rhombic shape in a plan view or a rectangular shape in a plan view. However, this is only an example, and a shape of each of the emission areas EA of the sub-display area SBDA according to one or more embodiments in a plan view is not limited to that illustrated in FIG. 7. That is, each of the emission areas EA of the sub-display area SBDA may have a polygonal shape such as a quadrangular shape, a pentagonal shape, or a hexagonal shape in a plan view or have a circular shape or an elliptical shape, in a plan view, including a curved edge.

The emission areas EA of at least one sub-display area SBDA (see FIG. 3) may include first emission areas EA1 for emitting light of a first wavelength band, second emission areas EA2 for emitting light of a second wavelength band lower than the first wavelength band, and third emission areas EA3 for emitting light of a third a wavelength band lower than the second wavelength band.

In at least one sub-display area SBDA (see FIG. 3), the first emission areas EA1 and the third emission areas EA3 may be alternately disposed along the first direction DR1 or the second direction DR2.

In at least one sub-display area SBDA (see FIG. 3), the second emission areas EA2 may be arranged side by side along the first direction DR1 or the second direction DR2.

In addition, the second emission areas EA2 may neighbor to the first emission areas EA1 and the third emission areas EA3 in the diagonal directions DR4 and DR5 crossing the first direction DR1 and the second direction DR2.

Pixels PX displaying each luminance and color may be provided by the first emission areas EA1, the second emission areas EA2, and the third emission areas EA3 adjacent to each other from among such emission areas EA.

According to one or more embodiments, in order to reduce visibility of the light transmitting area TRSA, the emission areas EA of at least one sub-display area SBDA (see FIG. 3) may be disposed at a greater width than the emission areas EA (see FIG. 5) of the main display area MDA (see FIG. 3).

The element layer 130 (see FIG. 4) may include light emitting elements LE (see FIG. 8) respectively disposed in the emission areas EA of at least one sub-display area SBDA (see FIG. 3).

The circuit layer 120 (see FIG. 4) may include sub-light emitting pixel drivers SEPD electrically connected to the light emitting elements LE (see FIG. 8) of the element layer 130 (see FIG. 4) disposed in the emission areas EA of at least one sub-display area SBDA (see FIG. 3).

The sub-light emitting pixel drivers SEPD may include a first sub-light emitting pixel driver SEPD1 electrically connected to a light emitting element LE (see FIG. 8) disposed in the first emission area EA1 of at least one sub-display area SBDA (see FIG. 3), a second sub-light emitting pixel driver SEPD2 electrically connected to a light emitting element LE (see FIG. 8) disposed in the second emission area EA2 of at least one sub-display area SBDA (see FIG. 3), and a third sub-light emitting pixel driver SEPD3 electrically connected to a light emitting element LE (see FIG. 8) disposed in the third emission area EA3 of at least one sub-display area SBDA (see FIG. 3).

The first sub-light emitting pixel drivers SEPD1 and the third sub-light emitting pixel drivers SEPD3 may be alternately arranged along the second direction DR2.

The second sub-light emitting pixel drivers SEPD2 may be arranged side by side along the second direction DR2.

The second sub-light emitting pixel driver SEPD2 may be disposed between the first sub-light emitting pixel driver SEPD1 and the third sub-light emitting pixel driver SEPD3 in the first direction DR1.

The light transmitting area TRSA may neighbor to two or more emission areas EA, and may transmit light.

At least one optical device 18 (see FIG. 2) disposed under the substrate 110 (see FIG. 4) may overlap at least one sub-display area SBDA (see FIG. 2), and may operate based on light transmitted through the light transmitting areas TRSA of at least one sub-display area SBDA (see FIG. 2).

That is, even though the display device 100 according to one or more embodiments does not include a hole overlapping the optical device 18 (see FIG. 2), a function of the optical device 18 (see FIG. 2) may be relatively normally implemented.

Accordingly, a ratio of the display area DA (see FIG. 3) disposed in the display surface of the display device 100 (see FIG. 2) may be prevented from being decreased due to a disposition of the optical device 18 (see FIG. 2), and thus, display quality and aesthetics of the display device 100 may be improved.

Each of the light transmitting areas TRSA may neighbor to at least one pixel PX in each of the first direction DR1 and the second direction DR2.

A width of the light transmitting area TRSA the first direction DR1 in the first direction DR1 may be in a range similar to a multiple of a width of the pixel PX in the first direction DR1, and a width of the light transmitting area TRSA in the second direction DR2 may be in the range similar to the multiple of the width of the pixel PX in the first direction DR1. In one or more other embodiments, a width of the light transmitting area TRSA in the second direction DR2 may be in the range similar to the multiple of the width of the pixel PX in the second direction DR2.

In this case, the light transmitting areas TRSA may be disposed alternately with two or more pixels PX along the second direction DR2. In addition, the light transmitting areas TRSA may be disposed alternately with at least one pixel PX along the first direction DR1.

In order to improve a light transmitting property of the light transmitting area TRSA, the light emitting elements LE (see FIG. 8) disposed in the emission areas EA of at least one sub-display area SBDA (see FIG. 3) and the sub-light emitting pixel drivers SEPD electrically connected to the light emitting elements LE do not overlap the light transmitting area TRSA.

Referring to FIG. 8, the display device 100 according to one or more embodiments may include a light transmitting hole TRH overlapping the light transmitting area TRSA.

As an example, in order to reduce light loss, the light transmitting hole TRH may penetrate through the element layer 130 and the circuit layer 120.

In this case, the first sealing layer 141 of the sealing layer 140 may be in contact with the substrate 110 through the light transmitting hole TRH.

According to one or more embodiments, the element layer 130 may include light emitting elements LE disposed in the emission areas EA of at least one sub-display area SBDA (see FIG. 3).

The light emitting elements LE are substantially the same as the light emitting elements LE (see FIG. 6) disposed in the main display area MDA (see FIG. 3) except that they are disposed in at least one sub-display area SBDA (see FIG. 3), and an overlapping description thereof will thus be omitted below.

FIG. 9 is a block diagram illustrating the display device of FIG. 2.

Referring to FIG. 9, the circuit layer 120 of the display device 100 according to one or more embodiments may include light emitting pixel drivers EPD electrically connected to the light emitting elements LE (see FIGS. 6 and 8) disposed in the emission areas EA of the display area DA.

According to one or more embodiments, the light emitting pixel drivers EPD may include the main light emitting pixel drivers MEPD arranged in the main display area MDA (see FIG. 3) and the sub-light emitting pixel drivers SEPD arranged in at least one sub-display area SBDA (see FIG. 3).

The circuit layer 120 may further include gate lines GL transmitting gate signals to the light emitting pixel drivers EPD and data lines DL transmitting data signals Vdata (see FIG. 10) to the light emitting pixel drivers EPD.

According to one or more embodiments, the display device 100 may further include a display driving circuit 200 for outputting the data signals Vdata (see FIG. 10) of the light emitting pixel drivers EPD to the data lines DL in order to control luminance of each of the light emitting elements LE (see FIGS. 6 and 8).

According to one or more embodiments, the display device 100 may further include a gate driving circuit GTDR for outputting gate signals to the gate lines GL, a power supply unit 700 for supplying power and voltages to the light emitting pixel drivers EPD, and a timing controller 800 for controlling a driving timing of each of the display driving circuit 200 and the gate driving circuit GTDR.

The timing controller 800 receives an image signal supplied from the outside of the display device 100.

The timing controller 800 may output image data DATA and a data control signal DCS to the data driver 200.

The timing controller 800 may generate a scan control signal SCS for controlling an operation timing of the gate driving circuit GTDR.

The data driving circuit 200 may convert the image data DATA into analog data voltages and output the analog data voltages to the data lines DL.

The gate driving circuit GTDR may generate gate signals according to the scan control signal SCS and sequentially output the gate signals to the gate lines GL.

The gate lines GL may include a scan write line GWL for transmitting a scan write signal GW (see FIG. 10), a reset control line GRL for transmitting a reset control signal GR (see FIG. 10), an initialization control line GIL for transmitting an initialization control signal GI (see FIG. 10), a first emission control line ECL1 for transmitting a first emission control signal EC1 (see FIG. 10), and a second emission control line ECL2 for transmitting a second emission control signal EC2 (see FIG. 10).

The gate signals may have pulses changed into a first gate level voltage or a second gate level voltage.

The power supply unit 700 may supply various power and voltages required for driving the light emitting pixel drivers EPD.

As an example, the power supply unit 700 may supply a first power ELVDD (see FIG. 10) and a second power ELVSS (see FIG. 10) for generating driving signals transmitted to the light emitting elements LE, a reference voltage VREF (see FIG. 10) for initializing the light emitting pixel drivers EPD, and an initialization voltage VAINT (see FIG. 10) for initializing the light emitting elements LE (see FIG. 10).

FIG. 10 is an equivalent circuit diagram illustrating a main light emitting pixel driver of FIG. 5 according to one or more embodiments.

Referring to FIG. 10, the main light emitting pixel drivers MEPD of the circuit layer 120 (see FIG. 4) may be electrically connected to respective the light emitting elements LE disposed in the main display area MDA (see FIG. 3).

Each of the main light emitting pixel drivers MEPD may be electrically connected to a first power line VDL transmitting a first power ELVDD, and the light emitting elements LE may be electrically connected to a second power line VSL transmitting the second power ELVSS different from the first power ELVDD.

The second power ELVSS may have a lower voltage level than the first power ELVDD.

That is, an anode electrode of the light emitting element LE may be electrically connected to the main light emitting pixel driver MEPD, and a cathode electrode of the light emitting element LE may be electrically connected to the second power line VSL.

Each of the main light emitting pixel drivers MEPD may be electrically connected to a data line DL transmitting a data signal Vdata, a reference voltage line VRL transmitting a reference voltage VREF, and an initialization voltage line VAIL transmitting an initialization voltage VAINT.

Each of the main light emitting pixel drivers MEPD may be electrically connected to a scan write line GWL transmitting a scan write signal GW, a reset control line GRL transmitting a reset control signal GR, an initialization control line GIL transmitting an initialization control signal GI, a first emission control line ECL1 transmitting a first emission control signal EC1, and a second emission control line ECL2 transmitting a second emission control signal EC2.

Each of the main light emitting pixel drivers MEPD may include a first transistor T1 generating a driving current of the light emitting element LE, two or more transistors T2 to T6 electrically connected to the first transistor T1, and one or more capacitors C1 and C2.

A second transistor T2 may be electrically connected between a gate electrode of the first transistor T1 and the data line DL.

The second transistor T2 may be turned on by the scan write signal GW of the scan write line GWL.

When the second transistor T2 is turned on, the data signal Vdata of the data line DL may be transmitted to the gate electrode of the first transistor T1.

When a voltage difference between the gate electrode of the first transistor T1 and a second electrode of the first transistor T1 becomes greater than or equal to a threshold voltage of the first transistor T1 by the data signal Vdata applied to the gate electrode of the first transistor T1, the first transistor T1 may be turned on. Accordingly, a drain-source current of the first transistor T1 may be generated in a magnitude corresponding to the data signal Vdata.

A third transistor T3 may be electrically connected between the gate electrode of the first transistor T1 and the reference voltage line VRL.

The third transistor T3 may be turned on by the reset control signal GR of the reset control line GRL.

When the third transistor T3 is turned on, a potential of the gate electrode of the first transistor T1 may be initialized to the reference voltage VREF of the reference voltage line VRL.

A fourth transistor T4 may be electrically connected between the light emitting element LE and the initialization voltage line VAIL.

The fourth transistor T4 may be turned on by the initialization control signal GI of the initialization control line GIL.

When the fourth transistor T4 is turned on, a potential of the anode electrode of the light emitting element LE may be initialized to the initialization voltage VAINT of the initialization voltage line VAIL.

A fifth transistor T5 may be electrically connected between a first electrode of the first transistor T1 and the first power line VDL.

The fifth transistor T5 may be turned on by the first emission control signal EC1 of the first emission control line ECL1.

A sixth transistor T6 may be electrically connected between the second electrode of the first transistor T1 and the light emitting element LE.

The sixth transistor T6 may be turned on by the second emission control signal EC2 of the second emission control line ECL2.

When the fifth transistor T5 and the sixth transistor T6 are turned on, the first transistor T1 and the light emitting element LE may be connected to each other in series between the first power ELVDD and the second power ELVSS, the drain-source current of the first transistor T1 generated in the magnitude corresponding to the data signal Vdata may be transmitted to the light emitting element LE.

Consequently, the light emitting element LE may emit light of luminance corresponding to the data signal Vdata.

A first capacitor C1 may be electrically connected between the gate electrode of the first transistor T1 and the second electrode of the first transistor T1.

The first capacitor C1 may be charged with the data signal Vdata applied to the gate electrode of the first transistor T1, and a turn-on state of the first transistor T1 may be maintained for a selected period due to a voltage charged in the first capacitor C1.

A second capacitor C2 may be electrically connected between the second electrode of the first transistor T1 and the first power line VDL.

The voltage of the first capacitor C1 may correspond to a potential difference between the gate electrode of the first transistor T1 and the second electrode of the first transistor, may be changed by the data signal Vdata, and may be divided by the second capacitor C2.

That is, a potential of the second electrode of the first transistor T1 may be maintained by the second capacitor C2 regardless of the gate electrode of the first transistor T1 and the first capacitor C1.

Consequently, a magnitude of a current flowing between the first electrode of the first transistor T1 and the second electrode of the first transistor T1, that is, the driving current to be transmitted to the light emitting element LE may be increased, and thus, luminance of the light emitting element LE may be increased.

According to one or more embodiments, the first transistor T1 may include a gate electrode facing one surface of a channel portion and a gate additional electrode facing the other surface of the channel portion. That is, the channel portion of the first transistor T1 may be interposed between the gate electrode and the gate additional electrode.

The gate electrode of the first transistor T1 may be electrically connected to the second transistor T2.

The gate additional electrode of the first transistor T1 may be electrically connected to the second electrode of the first transistor T1.

Accordingly, when the data signal Vdata is applied to the gate electrode of the first transistor T1 and the first transistor T1 is in a turn-on state, another portion of the channel portion of the first transistor T1 adjacent to the gate additional electrode may be activated to be lower (e.g., to have lower electron mobility) than a portion of the channel portion of the first transistor T1 adjacent to the gate electrode.

Therefore, electron mobility of the channel portion of the first transistor T1 is reduced, and thus, a gradient of a current curve indicating a relationship between a voltage of the gate electrode and a drain-source current of the first transistor T1 may become gentle. Accordingly, a driving voltage range of the first transistor T1 may be increased, and thus, easiness in controlling luminance may be improved.

According to one or more embodiments, the first transistor T1 may be an N-type metal oxide semiconductor field effect transistor (MOSFET).

In addition, at least some of the second to sixth transistors T2 to T6 may be P-type MOSFETs.

As an example, the fifth transistor T5 and the sixth transistor T6 may be P-type MOSFETs, and the second transistor T2, the third transistor T3, and the fourth transistor T4 may be N-type MOSFETs.

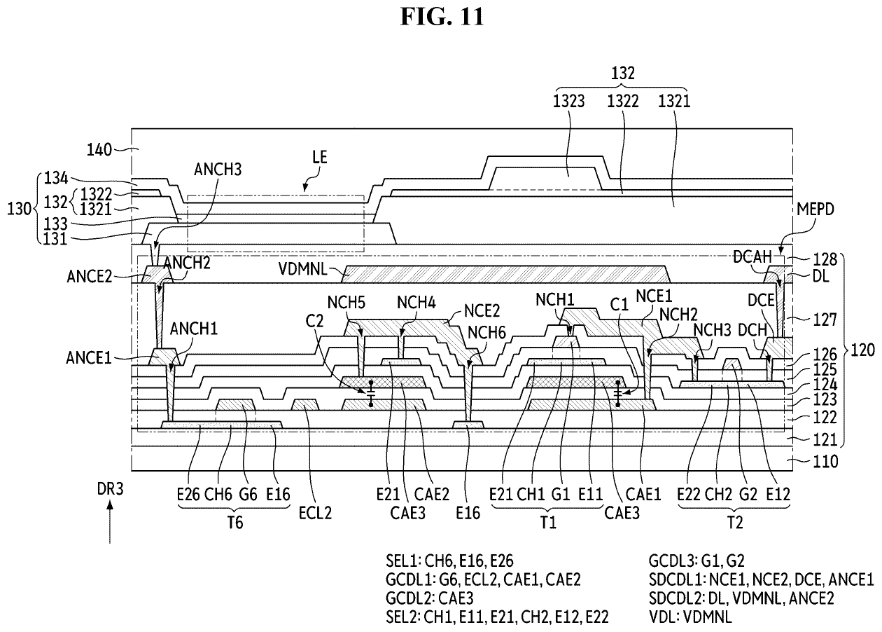

Accordingly, in one or more embodiments, the circuit layer 120 may include a first semiconductor layer SEL1 (see FIG. 11) for providing the P-type MOSFET, and a second semiconductor layer SEL2 (see FIG. 11) for providing the N-type MOSFET.

FIG. 11 is a cross-sectional view illustrating a first transistor, a second transistor, a sixth transistor, a first capacitor, a second capacitor, and a light emitting element of FIG. 10.

Referring to FIG. 11, the display device 100 according to one or more embodiments may include a substrate 110, a circuit layer 120 disposed on the substrate 110, and an element layer 130 disposed on the circuit layer 120.

The display device 100 may further include a sealing layer 140 disposed on the element layer 130.

According to one or more embodiments, the circuit layer 120 may include a buffer layer 121 disposed on the substrate 110, a first semiconductor layer SEL1 disposed on the buffer layer 121, a first interlayer insulating layer 124 disposed on the first semiconductor layer SEL1, and a second semiconductor layer SEL2 disposed on the first interlayer insulating layer 124 and including an oxide semiconductor material.

The circuit layer 120 may further include a first gate insulating layer 122 covering the first semiconductor layer SEL1, a first gate conductive layer GCDL1 disposed on the first gate insulating layer 122, a second gate insulating layer 123 covering the first gate conductive layer GCDL1, a second gate conductive layer GCDL2 disposed on the second gate insulating layer 123, a third gate insulating layer 125 covering the second semiconductor layer SEL2, a third gate conductive layer GCDL3 disposed on the third gate insulating layer 125, and a first source-drain conductive layer SDCDL1 disposed on a second interlayer insulating layer 126.

The first interlayer insulating layer 124 covers the second gate conductive layer GCDL2, and the second interlayer insulating layer 126 covers the third gate conductive layer GCDL3.

According to one or more embodiments, the circuit layer 120 may further include a first planarization layer 127 covering the first source-drain conductive layer SDCDL1, a second source-drain conductive layer SDCDL2 disposed on the first planarization layer 127, and a second planarization layer 128 covering the second source-drain conductive layer SDCDL2.

As illustrated in FIG. 10, each of the main light emitting pixel drivers MEPD may include the first transistor T1, and the second transistor T2, the third transistor T3, the fourth transistor T4, the fifth transistor T5, the sixth transistor T6, the first capacitor C1, and the second capacitor C2 that are electrically connected to the first transistor T1.

Each of the first transistor T1, the second transistor T2, the third transistor T3, the fourth transistor T4, the fifth transistor T5, and the sixth transistor T6 may include a gate electrode, a channel portion overlapping the gate electrode, a first electrode portion connected to one side of the channel portion, and a second electrode portion connected to the other side of the channel portion.

Hereinafter, the “first electrode portion” and the “second electrode portion” electrically connected to opposite ends of the “channel portion” of the “transistor” may be referred to as a “first electrode” and a “second electrode,” respectively.

According to one or more embodiments, the first, second, third, and fourth transistors T1, T2, T3, and T4 may be N-type MOSFETs, and the fifth and sixth transistors T5 and T6 may be P-type MOSFETs.

A channel portion CH6, a first electrode portion E16, and a second electrode portion E26 of the sixth transistor T6 provided as the P-type MOSFET may be disposed at the first semiconductor layer SEL1.

A gate electrode G6 of the sixth transistor T6 may be disposed at the first gate conductive layer GCDL1.

The gate electrode G6 of the sixth transistor T6 may be electrically connected to the second emission control line ECL2.

The second emission control line ECL2 may be disposed at the first gate conductive layer GCDL1 together with the gate electrode G6 of the sixth transistor T6.

As an example, the gate electrode G6 of the sixth transistor T6 may be a portion of the second emission control line ECL2 crossing the channel portion CH6 of the sixth transistor T6.

As an example, the first semiconductor layer SEL1 may include a silicon semiconductor material such as polysilicon or amorphous silicon.

That is, the sixth transistor T6 may include the channel portion CH6 disposed at the first semiconductor layer SEL1, the first electrode portion E16 disposed at the first semiconductor layer SEL1 and connected to one side of the channel portion CH6, the second electrode portion E26 disposed at the first semiconductor layer SEL1 and connected to the other side of the channel portion CH6, and the gate electrode G6 disposed at the first gate conductive layer GCDL1 and overlapping the channel portion CH6 in the third direction DR3.

The first electrode portion E16 of the sixth transistor T6 may be electrically connected to a second electrode portion E21 of the first transistor T1 through a second node connection electrode NCE2.

The second electrode portion E26 of the sixth transistor T6 may be electrically connected to an anode electrode 131 through a first anode connection electrode ANCE1 and a second anode connection electrode ANCE2.

The first anode connection electrode ANCE1 may be disposed at the first source-drain conductive layer SDCDL1 disposed on the second interlayer insulating layer 126, and may be electrically connected to the second electrode E26 of the sixth transistor T6 through a first anode connection hole ANCH1.

The first anode connection hole ANCH1 may penetrate through the second interlayer insulating layer 126, the third gate insulating layer 125, the first interlayer insulating layer 124, the second gate insulating layer 123, and the first gate insulating layer 122.

The second anode connection electrode ANCE2 may be disposed at the second source-drain conductive layer SDCDL2 disposed on the first planarization layer 127, and may be electrically connected to the first anode connection electrode ANCE1 through a second anode connection hole ANCH2 penetrating through the first planarization layer 127.

The anode electrode 131 may be disposed on the second planarization layer 128, and may be electrically connected to the second anode connection electrode ANCE2 through a third anode connection hole ANCT3 penetrating through the second planarization layer 128.

The fifth transistor T5 is the same P-type MOSFET as the sixth transistor T6, and an overlapping description thereof will thus be omitted below.

The first transistor T1 and the second transistor T2 formed as the N-type MOSFETs may include, respectively, channel portions CH1 and CH2, first electrode portions E11 and E12, and second electrode portions E21 and E22 disposed at the second semiconductor layer SEL2, and gate electrodes G1 and G2 disposed at the third gate conductive layer GCDL3 and overlapping the channel portions CH1 and CH2, respectively.

The second semiconductor layer SEL2 may include an oxide semiconductor material.

The first transistor T1 may include the channel portion CH1 disposed at the second semiconductor layer SEL2, the first electrode portion E11 disposed at the second semiconductor layer SEL2 and connected to one side of the channel portion CH1, the second electrode portion E21 disposed at the second semiconductor layer SEL2 and connected to the other side of the channel portion CH1, and the gate electrode G1 disposed at the third gate conductive layer GCDL3 and overlapping the channel portion CH1 in the third direction DR3.

An upper surface of the channel portion CH1 of the first transistor T1 may face the gate electrode G1.

In addition, a lower surface of the channel portion CH1 of the first transistor T1 may face a third capacitor electrode CAE3.

That is, the third capacitor electrode CAE3 may be the gate additional electrode of the first transistor T1.

The third capacitor electrode CAE3 may be electrically connected to the second electrode portion E21 of the first transistor T1 through the second node connection electrode NCE2.

The second transistor T2 may include the channel portion CH2 disposed at the second semiconductor layer SEL2, the first electrode portion E12 disposed at the second semiconductor layer SEL2 and connected to one side of the channel portion CH2, the second electrode portion E22 disposed at the second semiconductor layer SEL2 and connected to the other side of the channel portion CH2, and the gate electrode G2 disposed at the third gate conductive layer GCDL3 and overlapping the channel portion CH2.

The first electrode portion E12 of the second transistor T2 may be electrically connected to the data line DL through a data connection electrode DCE.

The data connection electrode DCE may be disposed at the first source-drain conductive layer SDCDL1 disposed on the second interlayer insulating layer 126, and may be electrically connected to the first electrode portion E12 of the second transistor T2 through a data connection hole DCH.

The data connection hole DCH may penetrate through the second interlayer insulating layer 126 and the third gate insulating layer 125.

The data line DL may be disposed at the second source-drain conductive layer SDCDL2 disposed on the first planarization layer 127, and may be electrically connected to the data connection electrode DCE through a data additional connection hole DCAH penetrating through the first planarization layer 127.

The first gate conductive layer GCDL1 may include a first capacitor electrode CAE1 and a second capacitor electrode CAE2 spaced (e.g., spaced apart) from each other.

The second capacitor electrode CAE2 may be electrically connected to the first power line VDL (see FIG. 10).

The first capacitor electrode CAE1 may be electrically connected to the gate electrode G1 of the first transistor T1 and the second electrode portion E22 of the second transistor T2 through a first node connection electrode NCE1.

The first node connection electrode NCE1 may be disposed at the first source-drain conductive layer SDCDL1 disposed on the second interlayer insulating layer 126.

The first node connection electrode NCE1 may be electrically connected to the gate electrode G1 of the first transistor T1 through a first node connection hole NCH1, electrically connected to the first capacitor electrode CAE1 through a second node connection hole NCH2, and electrically connected to the second electrode portion E22 of the second transistor T2 through a third node connection hole NCH3.

The second electrode portion E21 of the first transistor T1 may be electrically connected to the first electrode E16 of the sixth transistor T6 and the third capacitor electrode CAE3 through the second node connection electrode NCE2.

The third capacitor electrode CAE3 may be disposed at the second gate conductive layer GCDL2 disposed on the second gate insulating layer 123.

The second node connection electrode NCE2 may be disposed at the first source-drain conductive layer SDCDL1 disposed on the second interlayer insulating layer 126.

The second node connection electrode NCE2 may be electrically connected to the second electrode E21 of the first transistor T1 through a fourth node connection hole NCH4, electrically connected to the third capacitor electrode CAE3 through a fifth node connection hole NCH5, and electrically connected to the first electrode portion E16 of the sixth transistor T6 through a sixth node connection hole NCH6.

Because the first capacitor electrode CAE1 is electrically connected to the gate electrode G1 of the first transistor T1 and the third capacitor electrode CAE3 is electrically connected to the second electrode E21 of the first transistor T1, the first capacitor C1 may be formed in an area where the first capacitor electrode CAE1 and the third capacitor electrode CAE3 overlap each other (e.g., overlap each other in the third direction DR3).

Because the second capacitor electrode CAE2 is electrically connected to the first power line VDL (see FIG. 10) and the third capacitor electrode CAE3 is electrically connected to the second electrode E21 of the first transistor T1, the second capacitor C2 may be formed in an area where the second capacitor electrode CAE2 and the third capacitor electrode CAE3 overlap each other (e.g., overlap each other in the third direction DR3).

The first power line VDL may include a power main line VDMNL disposed at the second source-drain conductive layer SDCDL2.

The third transistor T3 and the fourth transistor T4 are the same N-type MOSFETs as the first transistor T1 and the second transistor T2, and an overlapping description thereof will thus be omitted below.

The element layer 130 may be disposed on the circuit layer 120, and may include light emitting elements LE respectively corresponding to the emission areas EA.

Each of the light emitting elements LE may include an anode electrode 131 and a cathode electrode 134 facing each other and a light emitting layer 133 disposed between the anode electrode 131 and the cathode electrode 134.

That is, the element layer 130 may include anode electrodes 131 disposed in the emission areas EA, a pixel defining layer 132 disposed in the non-emission area and covering edges of the anode electrodes 131, light emitting layers 133 disposed on the anode electrodes 131, and a cathode electrode 134 disposed on the light emitting layers 133 and the pixel defining layer 132.

The pixel defining layer 132 may include a first pixel defining layer 1321 disposed on the second planarization layer 128, a second pixel defining layer 1322 disposed on the first pixel defining layer 1321, and a spacer layer 1323 disposed on a portion of the second pixel defining layer 1322.

As an example, the first pixel defining layer 1321 may include a light absorbing insulating material for absorbing light or a light blocking insulating material for blocking light.

Alternatively, each of the light emitting elements LE may further include a first common layer disposed between the anode electrode 131 and the light emitting layer 133 and a second common layer disposed between the light emitting layer 133 and the cathode electrode 134.

The anode electrode 131 may be disposed in each of the emission areas EA, and may be electrically connected to one light emitting pixel driver EPD of the circuit layer 120. Such an anode electrode 131 may be referred to as a pixel electrode.

The light emitting layer 133 may include an organic light emitting material configured to convert electron-hole pairs into light.

The cathode electrode 134 may be disposed in the display area DA including the emission areas EA. The second power ELVSS (see FIG. 10) may be commonly applied to the cathode electrode 134. Such a cathode electrode 134 may be referred to as a common electrode.

The sealing layer 140 may be disposed on the element layer 130 and may cover the element layer 130.

As an example, the sealing layer 140 may include a first sealing layer disposed on the element layer 130 and made of an inorganic insulating material, a second sealing layer disposed on the first sealing layer, overlapping the element layer 130, and made of an organic insulating material, and a third sealing layer covering the second sealing layer, and made of an inorganic insulating material.

According to one or more embodiments, each of the light emitting pixel drivers EPD (see FIG. 9) of the circuit layer 120 (see FIG. 4) may include the third transistor T3 (see FIG. 10) for initializing the potential of the gate electrode G1 of the first transistor T1 and the fourth transistor T4 (see FIG. 10) for initializing the potential of the anode electrode 131 (see FIG. 11) of the light emitting element LE (see FIG. 10).

The channel portion of each of the third transistor T3 and the fourth transistor T4 may be disposed at the second semiconductor layer SEL2 (see FIG. 11) including the oxide semiconductor material.

Because the oxide semiconductor material may relatively sensitively react to light, a leakage current through the third transistor T3 and/or the fourth transistor T4 may be generated due to light incident through the substrate 110 (see FIG. 11), which may cause a malfunction of the light emitting pixel driver EPD.

In addition, according to one or more embodiments, each of the light emitting pixel drivers EPD (see FIG. 9) of the circuit layer 120 (see FIG. 4) may include the fifth transistor T5 (see FIG. 10) and the sixth transistor T6 (see FIG. 10) connected to the first transistor T1 (see FIG. 10) in series between the first power line VDL (see FIG. 10) and the light emitting element LE (see FIG. 10).

The channel portion of each of the fifth transistor T5 and the sixth transistor T6 may be disposed at the first semiconductor layer SEL1 (see FIG. 11), but the silicon semiconductor material of the first semiconductor layer SEL1 may also react to light having a relatively strong intensity. Accordingly, when a leakage current through the fifth transistor T5 and the sixth transistor T6 is generated, a malfunction of the light emitting element LE may be caused.

In particular, the sub-light emitting pixel drivers SEPD (see FIG. 7) disposed in at least one sub-display area SBDA (see FIGS. 2 and 3) are easily exposed to light incident through the light transmitting area TRSA (see FIG. 7), and thus, a leakage current may be more easily generated.

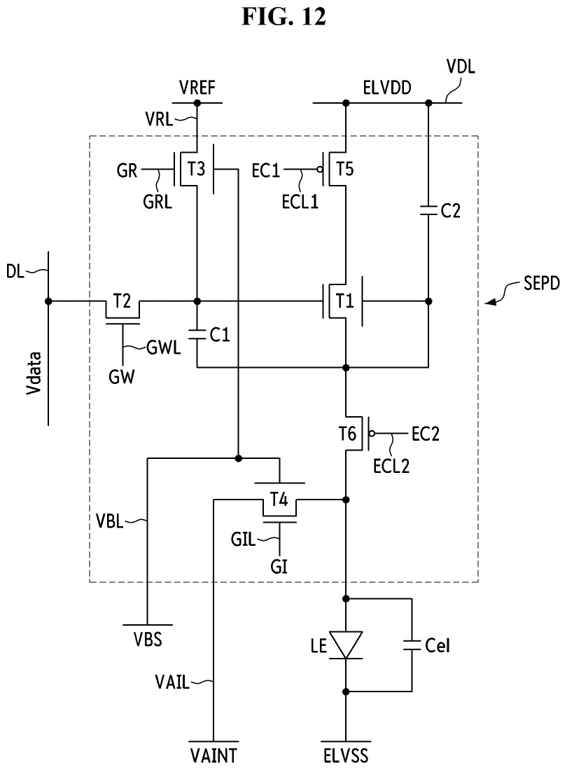

As such, according to one or more embodiments, the circuit layer 120 (see FIG. 4) may further include bias voltage lines VBL (see FIGS. 12-14) disposed in at least some of the light emitting pixel drivers EPD (see FIG. 9) of the display area DA (see FIG. 3) and transmitting bias voltages VBS (see FIGS. 12-14).

The bias voltage line VBL (see FIGS. 12-14) may overlap at least one of the channel portion of the third transistor T3, the channel portion of the fourth transistor T4, the channel portion of the fifth transistor T5, and the channel portion CH6 (see FIG. 11) of the sixth transistor T6.

According to one or more embodiments, at least some light emitting pixel drivers in which the bias voltage lines VBL (see FIGS. 12-14) are disposed from among the light emitting pixel drivers EPD (see FIG. 9) may be the sub-light emitting pixel drivers SEPD (see FIG. 7) disposed in at least one sub-display area SBDA (see FIGS. 2 and 3).

However, this is only an example, and the present disclosure may not be limited thereto. That is, the bias voltage lines VBL (see FIGS. 12-14) may be further disposed in some main light emitting pixel drivers MEPD (see FIG. 5) adjacent to at least one sub-display areas SBDA (see FIG. 2, FIG. 3) from among the main light emitting pixel drivers MEPD (see FIG. 5) of the main display area MDA (see FIG. 3) or may be entirely disposed in the light emitting pixel drivers EPD (see FIG. 9) of the display area DA (see FIG. 3).

However, for simplification of explanation, a case where at least some light emitting pixel drivers in which the bias voltage lines VBL (see FIGS. 12-14) are disposed from among the light emitting pixel drivers EPD (see FIG. 9) are the sub-light emitting pixel drivers SEPD (see FIG. 7) disposed in at least one sub-display area SBDA (see FIGS. 2 and 3) will hereinafter be described by way of example.

FIGS. 12-14 are equivalent circuit diagrams illustrating a sub-light emitting pixel driver of FIG. 7 according to one or more of embodiments.

According to an embodiment of FIG. 12, in each of the sub-light emitting pixel drivers SEPD, a channel portion of a third transistor T3 may be disposed between a gate electrode of the third transistor T3 and a bias voltage line VBL, and a channel portion of a fourth transistor T4 may be disposed between a gate electrode of the fourth transistor T4 and the bias voltage line VBL.

When the gate electrode of the third transistor T3 electrically connected to a reset control line GRL is a portion of the reset control line GRL, the channel portion of the third transistor T3 may overlap a portion of the reset control line GRL and a portion of the bias voltage line VBL.

In this case, a portion of the channel portion of the third transistor T3 facing a portion of the bias voltage line VBL may be activated to be lower (e.g., to have lower electron mobility) than a portion of the channel portion of the third transistor T3 facing a portion of the reset control line GRL. Therefore, a leakage current and a malfunction of the third transistor T3 may be reduced.

When the gate electrode of the fourth transistor T4 electrically connected to an initialization control line GIL is a portion of the initialization control line GIL, the channel portion of the fourth transistor T4 may overlap a portion of the initialization control line GIL and another portion of the bias voltage line VBL.

In this case, a portion of the channel portion of the fourth transistor T4 facing another portion of the bias voltage line VBL may be activated to be lower (e.g., to have lower electron mobility) than a portion of the channel portion of the fourth transistor T4 facing a portion of the initialization control line GIL. Therefore, a leakage current and a malfunction of the fourth transistor T4 may be reduced.

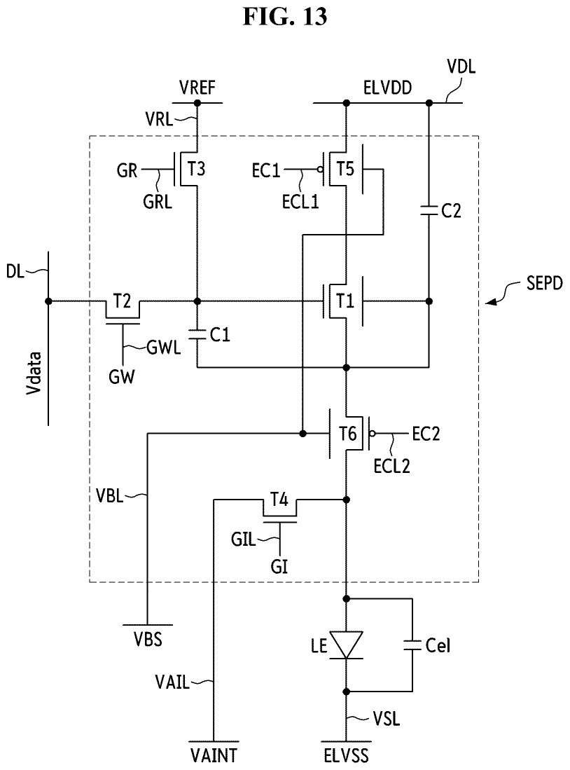

According to an embodiment of FIG. 13, in each of the sub-light emitting pixel drivers SEPD, a channel portion of a fifth transistor T5 may be disposed between a gate electrode of the fifth transistor T5 and the bias voltage line VBL, and a channel portion of a sixth transistor T6 may be disposed between a gate electrode of the sixth transistor T6 and the bias voltage line VBL.

When the gate electrode of the fifth transistor T5 electrically connected to a first emission control line ECL1 is a portion of the first emission control line ECL1, the channel portion of the fifth transistor T5 may overlap a portion of the first emission control line ECL1 and a portion of the bias voltage line VBL.

When the gate electrode of the sixth transistor T6 electrically connected to a second emission control line ECL2 is a portion of the second emission control line ECL2, the channel portion of the sixth transistor T6 may overlap a portion of the second emission control line ECL2 and another portion of the bias voltage line VBL.

In this case, light directed to the channel portion of each of the fifth transistor T5 and the sixth transistor T6 may be blocked by the gate electrode of each of the fifth transistor T5 and the sixth transistor T6 and the bias voltage line VBL, and thus, malfunctions of the fifth transistor T5 and the sixth transistor T6 may be reduced.

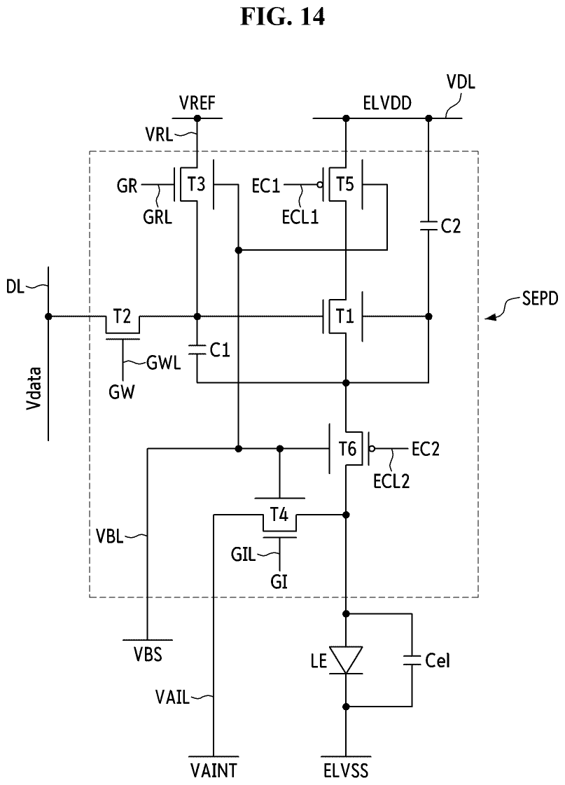

The sub-light emitting pixel driver SEPD according to an embodiment of FIG. 14 is substantially the same as or similar to the sub-light emitting pixel drivers SEPD according to an embodiment of FIG. 12 and an embodiment of FIG. 13 except that the bias voltage line VBL overlaps the channel portion of each of the third transistor T3, the fourth transistor T4, the fifth transistor T5, and the sixth transistor T6, and an overlapping description thereof will thus be omitted below.

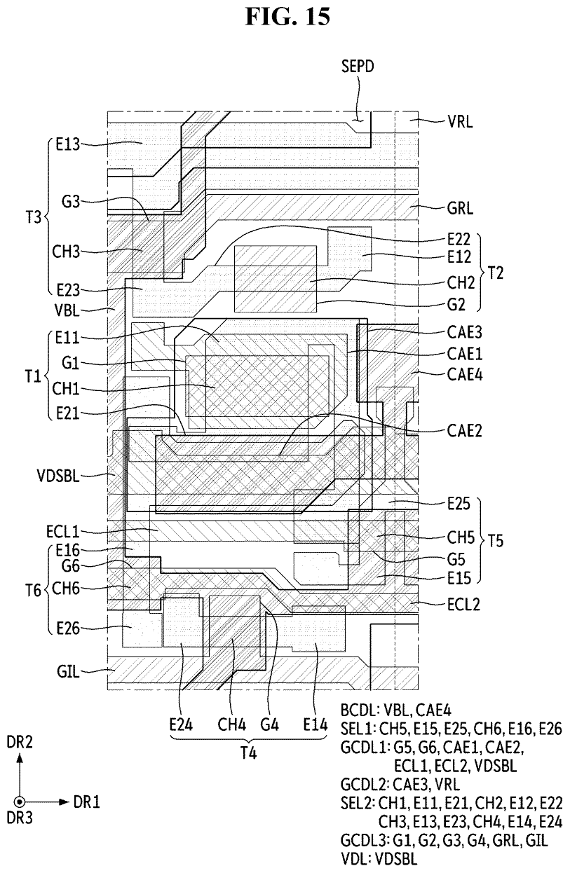

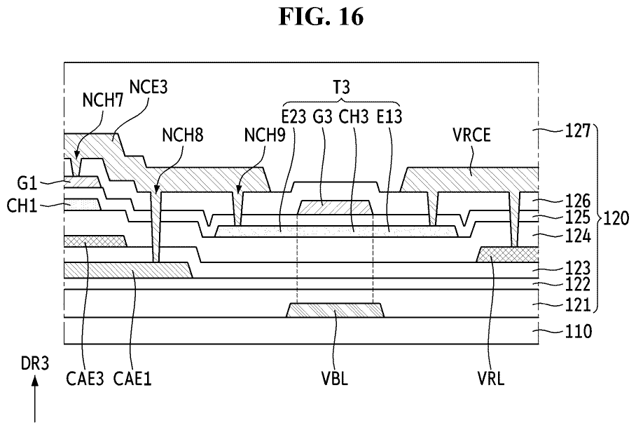

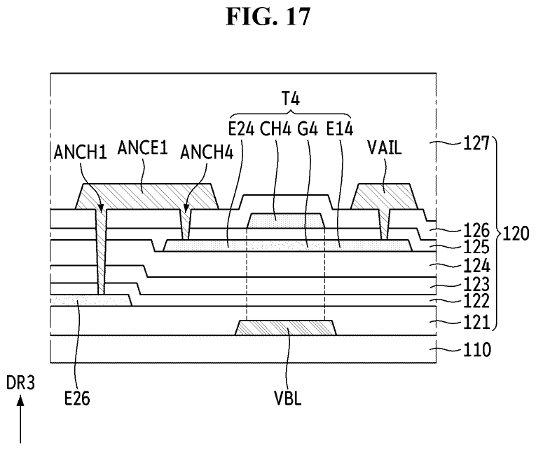

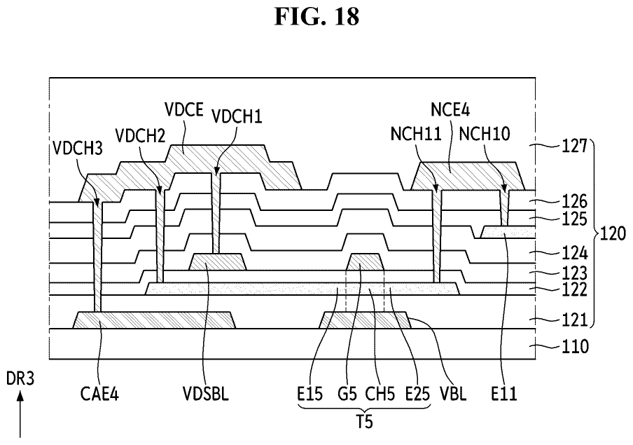

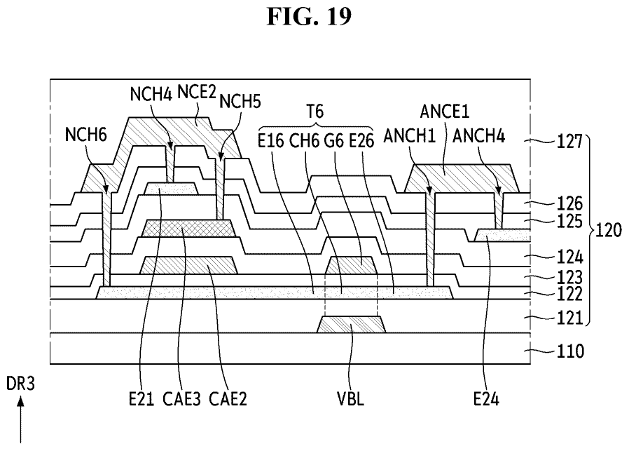

FIG. 15 is a plan view illustrating the sub-light emitting pixel driver according to the embodiment of FIG. 14. FIG. 16 is a cross-sectional view illustrating a third transistor according to the embodiment of FIG. 12 and the embodiment of FIG. 14. FIG. 17 is a cross-sectional view illustrating a fourth transistor according to the embodiment of FIG. 12 and the embodiment of FIG. 14. FIG. 18 is a cross-sectional view illustrating a fifth transistor according to the embodiment of FIG. 13 and the embodiment of FIG. 14. FIG. 19 is a cross-sectional view illustrating a sixth transistor according to the embodiment of FIG. 13 and the embodiment of FIG. 14.

As illustrated in FIG. 15, the circuit layer 120 (see FIG. 4) of the display device 100 according to one or more embodiments may include a light blocking conductive layer BCDL, a first semiconductor layer SEL1, a first gate conductive layer GCDL1, a second gate conductive layer GCDL2, a second semiconductor layer SEL2, and a third gate conductive layer GCDL3.

The first semiconductor layer SEL1 may include channel portions CH5 and CH6, first electrode portions E15 and E16, and second electrode portions E25 and E26 of the fifth transistor T5 and the sixth transistor T6.

The first gate conductive layer GCDL1 may include gate electrodes G5 and G6 of the fifth transistor T5 and the sixth transistor T6, a first emission control line ECL1, a second emission control line ECL2, a first capacitor electrode CAE1, a second capacitor electrode CAE2, and a power sub-line VDSBL.

Each of the first emission control line ECL1, the second emission control line ECL2, and the power sub-line VDSBL may extend in the first direction DR1.

The gate electrode G5 of the fifth transistor T5 may be a portion of the first emission control line ECL1.

The gate electrode G6 of the sixth transistor T6 may be a portion of the second emission control line ECL1.

The second capacitor electrode CAE2 may be a portion of the power sub-line VDSBL.

A first power line VDL transmitting a first power ELVDD (see FIG. 14) may include the power sub-line VDSBL.

The first capacitor electrode CAE1 and the second capacitor electrode CAE2 may be spaced (e.g., spaced apart) from each other.

The second gate conductive layer GCDL2 may include a third capacitor electrode CAE3 and a reference voltage line VRL.

The reference voltage line VRL may extend in the first direction DR1.

The third capacitor electrode CAE3 may overlap the first capacitor electrode CAE1 and the second capacitor electrode CAE2 in the third direction DR3.

The second semiconductor layer SEL2 may include channel portions CH1, CH2, CH3, and CH4, first electrode portions E11, E12, E13, and E14, and second electrode portions E21, E22, E23, and E24 of the first transistor T1, the second transistor T2, the third transistor T3, and the fourth transistor T4.

The third gate conductive layer GCDL3 may include gate electrodes G1, G2, G3, and G4 of first transistor T1, the second transistor T2, the third transistor T3, and the fourth transistor T4, a reset control line GRL, and an initialization control line GIL.

The reset control line GRL may extend in the first direction DR1, and may be adjacent to the reference voltage line VRL in the second direction DR2.

The gate electrode G3 of the third transistor T3 may be a portion of the reset control line GRL.

The gate electrode G4 of the fourth transistor T4 may be a portion of the initialization control line GIL.

When the bias voltage line VBL for preventing a leakage current due to light is disposed at the first gate conductive layer GCDL1 or the second gate conductive layer GCDL2, the bias voltage line VBL may avoid (e.g., may bypass) the first capacitor electrode CAE1, the second capacitor electrode CAE2, the first emission control line ECL1, the second emission control line ECL2, and the power sub-line VDSBL or may avoid (e.g., may bypass) the third capacitor electrode CAE3 and the reset voltage line VR. For this reason, a width of each of the sub-light emitting pixel drivers SEPD increases, and thus, a resolution of the sub-display area SBDA (see FIG. 3) may be reduced.

, In one or more embodiments, the circuit layer 120 (see FIG. 11) may include a light blocking conductive layer BCDL disposed on a substrate 110 (see FIGS. 16-19) and covered with a buffer layer 121 (see FIGS. 16-19) , and the bias voltage line VBL may be disposed at the light blocking conductive layer BCDL (see FIG. 15).

According to the embodiment of FIG. 14, the channel portion CH3 of the third transistor T3, the channel portion CH4 of the fourth transistor T4, the channel portion CH5 of the fifth transistor T5, and the channel portion CH6 of the sixth transistor that are disposed in each of the sub-emission drivers SEPD may overlap portions of the bias voltage line VBL, respectively.

As illustrated in FIGS. 15 and 16, the channel portion CH3 of the third transistor T3 disposed in each of the sub-light emitting pixel drivers SEPD according to one or more embodiments may overlap the gate electrode G3 of the third transistor T3 and the bias voltage line VBL in the third direction DR3.

The first electrode portion E13 of the third transistor T3 may be connected to one side of the channel portion CH3 of the third transistor T3 and electrically connected to the reference voltage line VRL through a reference voltage connection electrode VRCE.

The second electrode portion E23 of the third transistor T3 may be electrically connected to the gate electrode G1 of the first transistor T1 and the first capacitor electrode CAE1 through a third node connection electrode NCE3.

The third node connection electrode NCE3 may be electrically connected to the gate electrode G1 of the first transistor T1 through a seventh node connection hole NCH7, electrically connected to the first capacitor electrode CAE1 through an eighth node connection hole NCH8, and electrically connected to the second electrode portion E23 of the third transistor T3 through a ninth node connection hole NCH9.

As illustrated in FIGS. 15 and 17, the channel portion CH4 of the fourth transistor T4 disposed in each of the sub-light emitting pixel drivers SEPD according to one or more embodiments may overlap the gate electrode G4 of the fourth transistor T4 and the bias voltage line VBL in the third direction DR3.

The first electrode portion E14 of the fourth transistor T4 may be electrically connected to an initialization voltage line VAIL.

The second electrode portion E24 of the fourth transistor T4 may be electrically connected to a first anode connection electrode ANCE1.

The first anode connection electrode ANCE1 may be electrically connected to the second electrode portion E26 of the sixth transistor T6 (see FIG. 15) through a first anode connection hole ANCH1 and electrically connected to the second electrode portion E24 of the fourth transistor T4 through a fourth anode connection hole ANCH4.

As illustrated in FIGS. 15 and 18, the channel portion CH5 of the fifth transistor T5 disposed in each of the sub-light emitting pixel drivers SEPD according to one or more embodiments may overlap the gate electrode G5 of the fifth transistor T5 and the bias voltage line VBL in the third direction DR3.

The first electrode portion E15 of the fifth transistor T5 may be electrically connected to the power sub-line VDSBL through a power connection electrode VDCE.

The power connection electrode VDCE may be electrically connected to the power sub-line VDSBL through a first power connection hole VDCH1 and electrically connected to the first electrode portion E15 of the fifth transistor T5 through a second power connection hole VDCH2.

The first power line VDL transmitting the first power ELVDD (see FIG. 14) may include the power sub-line VDSBL.

A portion of the power sub-line VDSBL may be the second capacitor electrode CAE2 overlapping the third capacitor electrode CAE3.

According to one or more embodiments, each of the sub-light emitting pixel drivers SEPD may further include a fourth capacitor electrode CAE4 disposed at the light blocking conductive layer BCDL (see FIG. 15), overlapping the second capacitor electrode CAE2, and electrically connected to the first power line VDL (see FIG. 14).

The fourth capacitor electrode CAE4 may be electrically connected to the power sub-line VDSBL through a third power connection hole VDCH3 and the power connection electrode VDCE.

The second electrode portion E25 of the fifth transistor T5 may be electrically connected to the first electrode portion E11 of the first transistor T1 (see FIG. 14) through a fourth node connection electrode NCE4.

The fourth node connection electrode NCE4 may be electrically connected to the first electrode portion E11 of the first transistor T1 (see FIG. 14) through a tenth node connection hole NCH10 and electrically connected to the second electrode portion E25 of the fifth transistor T5 through an eleventh node connection hole NCH11.

As illustrated in FIGS. 15 and 19, the channel portion CH6 of the sixth transistor T6 disposed in each of the sub-light emitting pixel drivers SEPD according to one or more embodiments may overlap the gate electrode G6 of the sixth transistor T6 and the bias voltage line VBL in the third direction DR3.

The first electrode portion E16 of the sixth transistor T6 may be electrically connected to the second electrode portion E21 of the first transistor T1 (see FIG. 14) and the third capacitor electrode CAE3 through a second node connection electrode NCE2.

The second electrode portion E26 of the sixth transistor T6 may be electrically connected to the first anode connection electrode ANCE1.

The display area DA (see FIG. 3) of the display device 100 according to one or more embodiments may include the main display area MDA (see FIG. 3) where the emission areas EA (see FIG. 5) are arranged side by side and at least one sub-display area SBDA (see FIG. 3) including the emission areas EA (see FIG. 7) and the light transmitting area TRSA (see FIG. 7).

According to one or more embodiments, in order to lower the visibility of the light transmitting area TRSA disposed in at least one sub-display area SBDA, luminance of the emission areas EA (see FIG. 7) disposed in at least one sub-display area SBDA needs to be higher than luminance of the emission areas EA (see FIG. 5) disposed in the main display area MDA.

Accordingly, the sub-light emitting pixel drivers SEPD disposed in at least one sub-display area SBDA may include a second capacitor C2 (see FIGS. 12-14) having a greater capacitance (e.g., greater in capacitance compared to the first capacitor C1) in order to generate a greater driving current than the main light emitting pixel drivers MEPD (see FIG. 5) disposed in the main display area MDA.

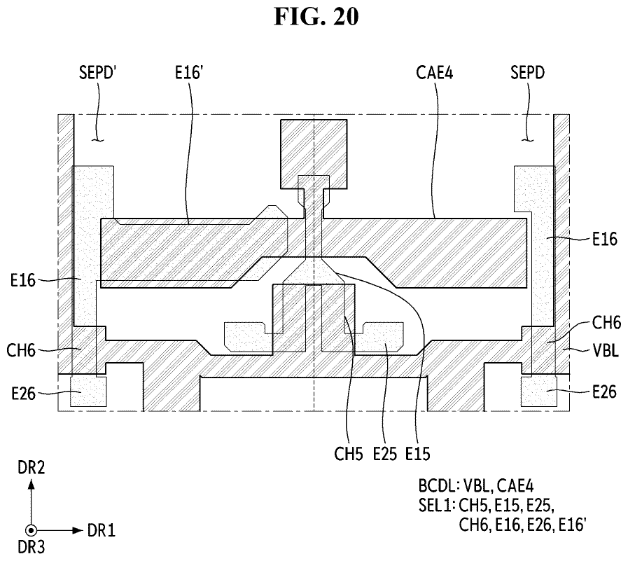

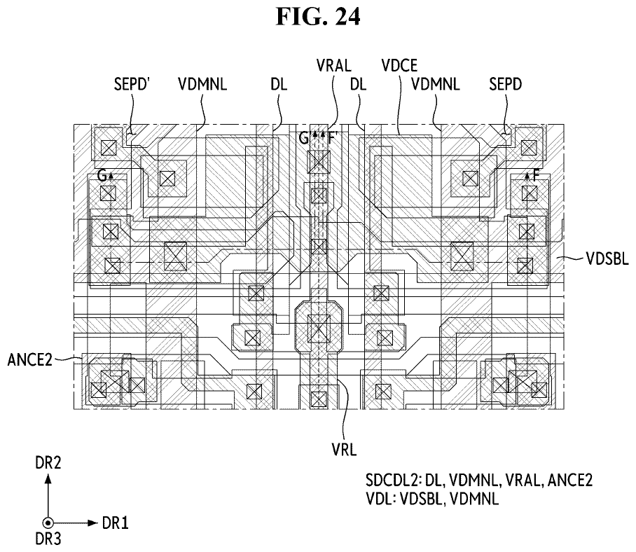

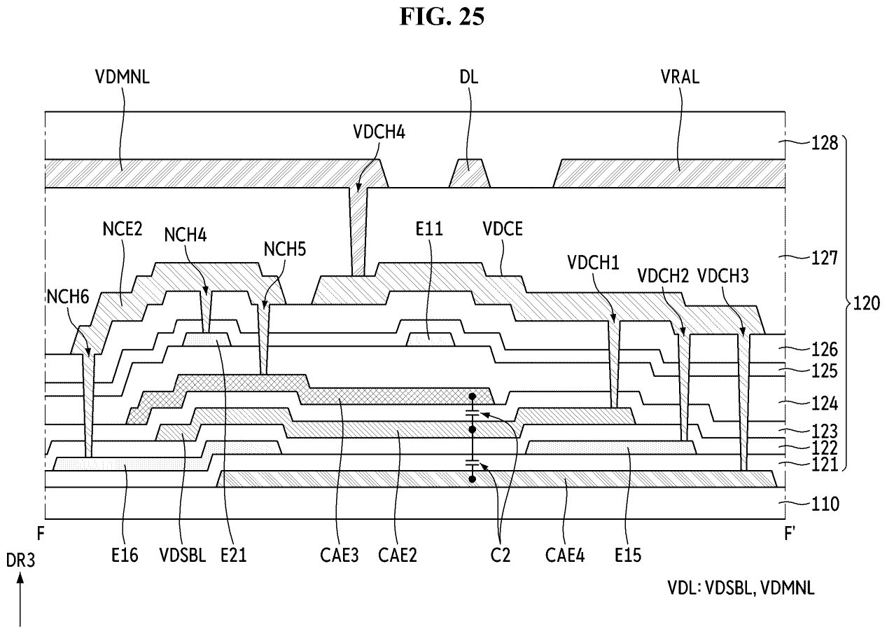

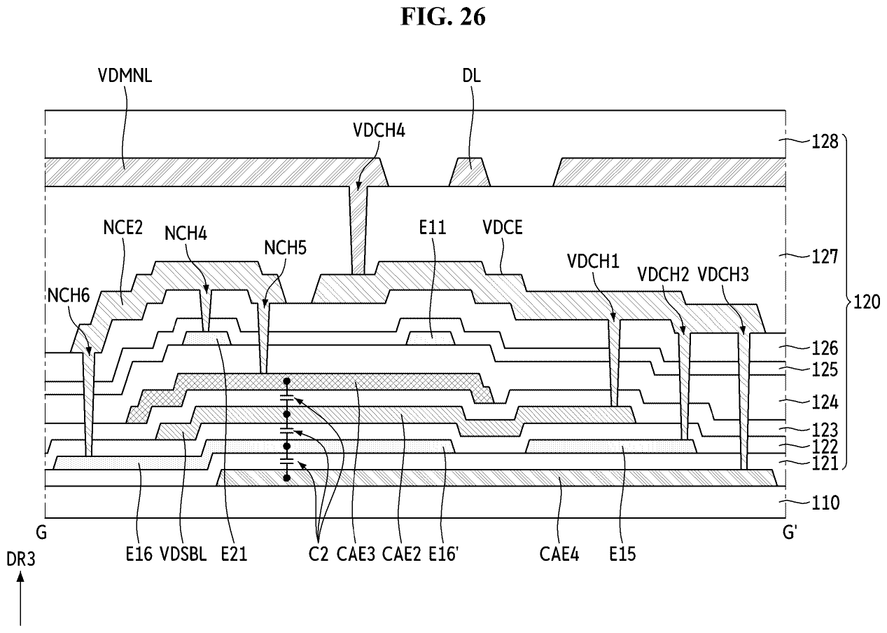

FIGS. 20-24 are plan views illustrating two adjacent sub-light emitting pixel drivers according to one or more embodiments. FIG. 25 is a cross-sectional view taken along the line F-F′ of FIG. 24. FIG. 26 is a cross-sectional view taken along the line G-G′ of FIG. 24.

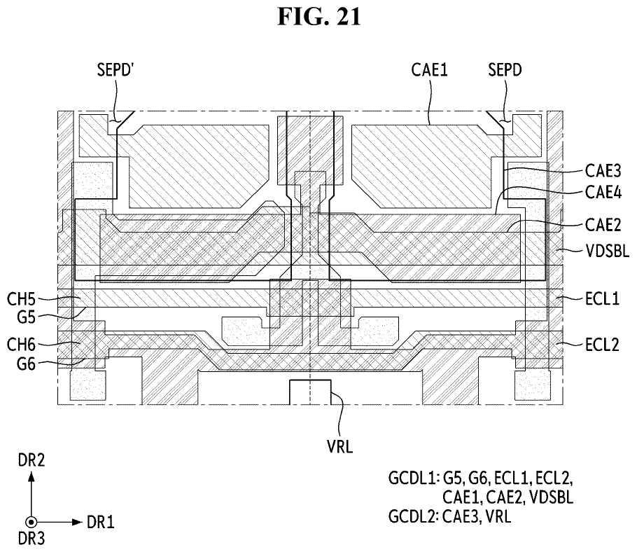

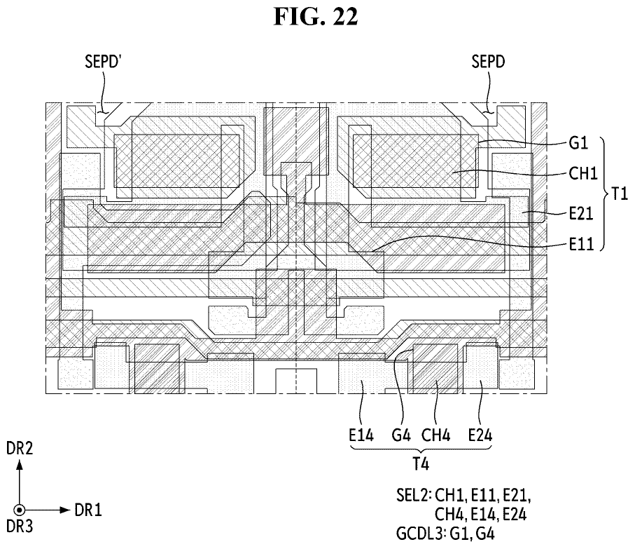

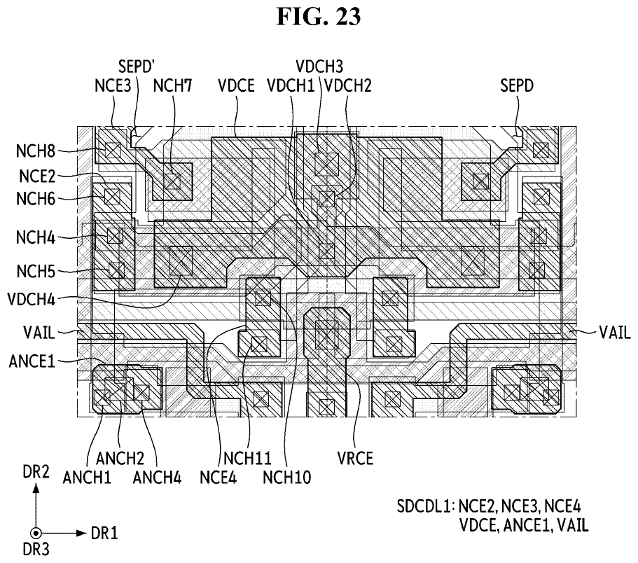

FIG. 20 illustrates a light blocking conductive layer BCDL and a first semiconductor layer SEL1, FIG. 21 illustrates a first gate conductive layer GCDL1 and a second gate conductive layer GCDL2, and FIG. 22 illustrates a second semiconductor layer SEL2 and a third gate conductive layer GCDL3. FIG. 23 illustrates a first source-drain conductive layer SDCDL1, and FIG. 24 illustrates a second source-drain conductive layer SDCDL2.

FIGS. 20-24 are partially the same as or similar to FIG. 15, and an overlapping description will thus be omitted below.

As illustrated in FIG. 20, according to one or more embodiments, each of sub-light emitting pixel drivers SEPD and SEPD′ may include a fourth capacitor electrode CAE4 disposed at the light blocking conductive layer BCDL.

In each of the sub-light emitting pixel drivers SEPD and SEPD′, channel portions CH5 and CH6, first electrode portions E15 and E16 and E16′, and second electrode portions E25 and E26 of the fifth transistor T5 (see FIG. 14) and the sixth transistor T6 (see FIG. 14) may be disposed at the first semiconductor layer SEL1.

According to one or more embodiments, in each of the sub-light emitting pixel drivers SEPD and SEPD′, the channel portions CH5 and CH6 of the fifth transistor T5 (see FIG. 14) and the sixth transistor T6 (see FIG. 14) may overlap the bias voltage line VBL disposed at the light blocking conductive layer BCDL.

In at least some sub-light emitting pixel drivers SEPD′ of the sub-light emitting pixel drivers SEPD and SEPD′, the first electrode portion of the sixth transistor T6 (see FIGS. 12-14) may include a main electrode portion E16 connected to the channel portion CH6 of the sixth transistor T6 (see FIGS. 12 to 14) and an extension electrode portion E16′ extending from the main electrode portion E16 and overlapping the fourth capacitor electrode CAE4 in the third direction DR3.

As illustrated in FIG. 21, the first gate conductive layer GCDL1 may include gate electrodes G5 and G6 of the fifth transistor T5 (see FIG. 14) and the sixth transistor T6 (see FIG. 14), a first emission control line ECL1, a second emission control line ECL2, a first capacitor electrode CAE1, a second capacitor electrode CAE2, and a power sub-line VDSBL.

The second capacitor electrode CAE2 may be a portion of the power sub-line VDSBL.

The fourth capacitor electrode CAE4 may overlap one of the first electrode portion E16 and E16′ of the first electrode portion E16 of the sixth transistor T6 (see FIG. 14) and the second capacitor electrode CAE2.

The second gate conductive layer GCDL2 may include a third capacitor electrode CAE3 and a reference voltage line VRL.

The third capacitor electrode CAE3 may overlap the first capacitor electrode CAE1 and the second capacitor electrode CAE2 in the third direction DR3.

As illustrated in FIG. 22, in each of the sub-light emitting pixel drivers SEPD and SEPD′, channel portions CH1 and CH4, first electrode portions E11 and E14, and second electrode portions E21 and E24 of the first transistor T1 and the fourth transistor T4 may be disposed at the second semiconductor layer SEL2.

Gate electrodes G1 and G4 of the first transistor T1 and the fourth transistor T4 may be disposed at the third gate conductive layer GCDL3.

The channel portion CH1 of the first transistor T1 may overlap the gate electrode G1 of the first transistor T1, the first capacitor electrode CAE1, and the third capacitor electrode CAE3 in the third direction DR3.

As illustrated in FIG. 23, the first source-drain conductive layer SDCDL1 may include a second node connection electrode NCE2, a third node connection electrode NCE3, a fourth node connection electrode NCE4, a power connection electrode VDCE, a first anode connection electrode ANCE1, and an initialization voltage line VAIL.

As illustrated in FIG. 24, the second source-drain conductive layer SDCDL2 may include a data line DL, a power main line VDMNL, a reference voltage additional line VRAL, and a second anode connection electrode ANCE2.

Each of the data line DL, the power main line VDMNL, and the reference voltage additional line VRAL may extend in the second direction DR2.

The first power line VDL may include a power sub-line VDSBL disposed at the first gate conductive layer GCDL1 (see FIG. 21) and extending in the first direction DR1 and a power main line VDMNL disposed at the second source-drain conductive layer SDCDL2 and extending in the second direction DR2.

In this case, the first power ELVDD (see FIG. 7) may be relatively evenly transmitted to the entire display area DA through a mesh-shaped line.

As illustrated in FIGS. 23-26, the second node connection electrode NCE2 may be electrically connected to the second electrode E21 of the first transistor T1 through a fourth node connection hole NCH4, electrically connected to the third capacitor electrode CAE3 through a fifth node connection hole NCH5, and electrically connected to the first electrode portion E16 of the sixth transistor T6 through a sixth node connection hole NCH6 (e.g., see FIGS. 19 and 25).

The power connection electrode VDCE may be electrically connected to the power sub-line VDSBL through a first power connection hole VDCH1, electrically connected to the first electrode portion E15 of the fifth transistor T5 through a second power connection hole VDCH2, and electrically connected to the fourth capacitor electrode CAE4 through a third power connection hole VDCH3.

The power main line VDMNL may be electrically connected to the power connection electrode VDCE through a fourth power connection hole VDCH4.

As illustrated in FIGS. 25 and 26, the second capacitor C2 may be formed in an overlapping area between the second capacitor electrode CAE2 and the third capacitor electrode CAE3.

As illustrated in FIG. 25, in some other sub-emission pixel drivers SEPD and SEPD′ of the sub-emission pixel drivers SEPD, the first electrode portion E16 of the sixth transistor T6 (see FIG. 14) does not include the extension electrode portion E16′, and thus, the fourth capacitor electrode CAE4 may overlap the second capacitor electrode CAE2 in the third direction DR3.

In this case, the second capacitor C2 may be further formed in an overlapping area between the second capacitor electrode CAE2 and the fourth capacitor electrode CAE4.

Therefore, capacitance of the second capacitor C2 may be increased without increasing a width of the second capacitor electrode CAE2 and a width of the third capacitor electrode CAE3. That is, luminance may be increased without causing a decrease in resolution.

As illustrated in FIG. 26, in at least some sub-light emitting pixel drivers SEPD and SEPD′ of the sub-light emitting pixel drivers SEPD′, the first electrode portion E16 of the sixth transistor T6 (see FIG. 14) includes the extension electrode portion E16′, and thus, the fourth capacitor electrode CAE4 may overlap the extension electrode portion E16′ of the first electrode portion E16 and E16′ of the sixth transistor T6 (see FIG. 14) in the third direction DR3.

In this case, the second capacitor C2 may be further formed in an overlapping area between the second capacitor electrode CAE2 and the first electrode portion E16 and E16′ of the sixth transistor T6 (see FIG. 14), and an overlapping area between the first electrode portion E16 and E16′ of the sixth transistor T6 (see FIG. 14) and the fourth capacitor electrode CAE4.

Therefore, the capacitance of the second capacitor C2 may be further increased without increasing the width of the second capacitor electrode CAE2 and the width of the third capacitor electrode CAE3. That is, the luminance may be further increased without causing a decrease in resolution.

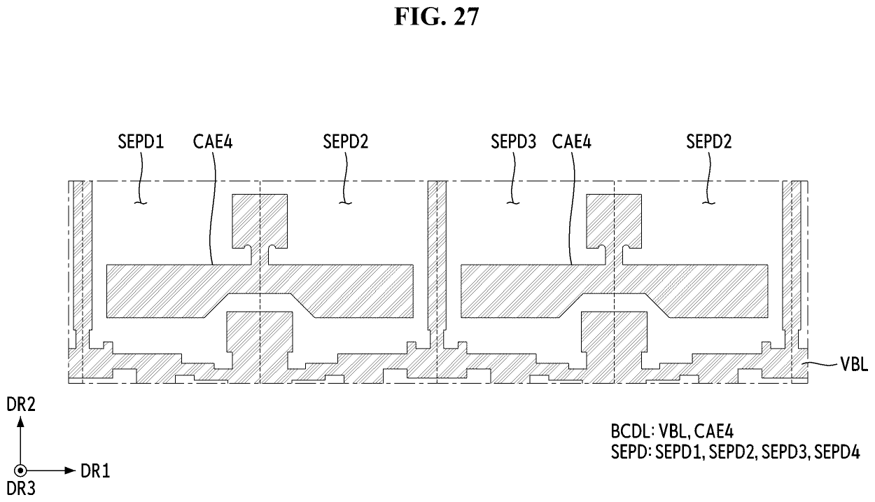

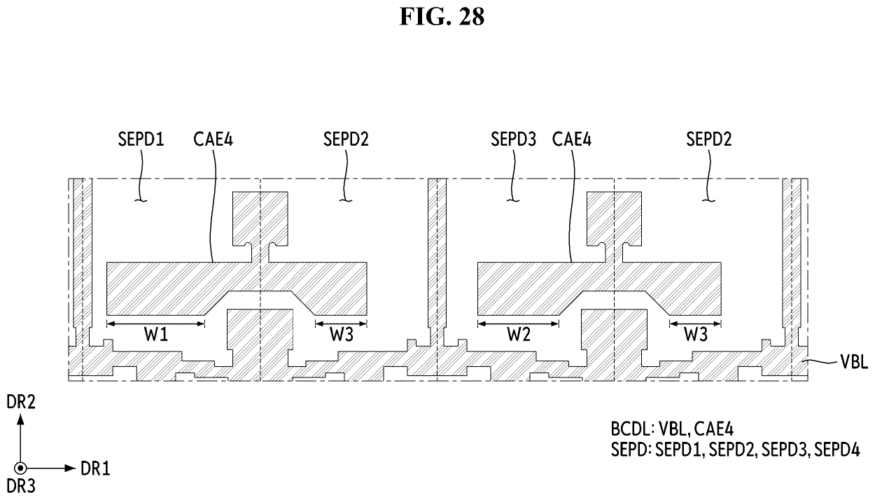

FIGS. 27 and 28 are plan views illustrating a fourth capacitor electrode according to one or more embodiments.

As illustrated in FIG. 27, according to one or more embodiments, the sub-light emitting pixel drivers SEPD may include fourth capacitor electrodes CAE4 having the same width.

In this case, capacitance of the second capacitor C2 increased by the fourth capacitor electrode CAE4 may be the same in all of the sub-light emitting pixel drivers SEPD. Consequently, operation characteristics of the sub-light emitting pixel drivers SEPD are similar to each other, and thus, luminance control of the light emitting elements LE (see FIG. 6) disposed in at least one sub-display area SBDA (see FIG. 3) may be relatively easy.

According to one or more embodiments, the sub-light emitting pixel drivers SEPD may include a first sub-light emitting pixel driver SEPD1 electrically connected to a light emitting element LE (see FIG. 8) disposed in the first emission area EA1 of at least one sub-display area SBDA (see FIG. 3), a second sub-light emitting pixel driver SEPD2 electrically connected to a light emitting element LE (see FIG. 8) disposed in the second emission area EA2 of at least one sub-display area SBDA (see FIG. 3), and a third sub-light emitting pixel driver SEPD3 electrically connected to a light emitting element LE (see FIG. 8) disposed in the third emission area EA3 of at least one sub-display area SBDA (see FIG. 3).

As illustrated in FIG. 28, a fourth capacitor electrode CAE4 of the first sub-light emitting pixel driver SEPD1 may be disposed at a first width W1, a fourth capacitor electrode CAE4 of the third sub-light emitting pixel driver SEPD3 may be disposed at a second width W2 smaller than the first width W1, and a fourth capacitor electrode CAE4 of the second sub-light emitting pixel driver SEPD2 may be disposed at a third width W3 smaller than the second width W2.

In this case, a luminance difference due to a width difference between the first emission area EA1, the second emission area EA2, and the third emission area EA3 may be compensated for by a width difference between the fourth capacitor electrodes CAE4. Consequently, display quality of the display device 100 may be improved.

The display device 100 according to one or more embodiments as described above may be applied to various electronic devices.

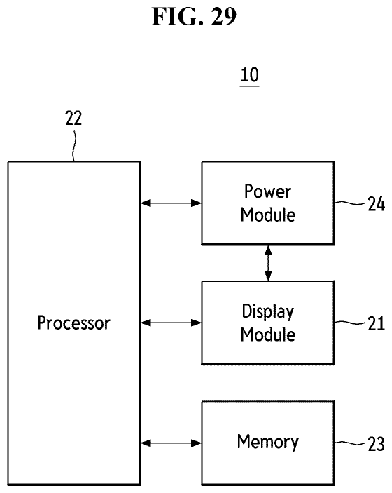

An electronic device 10 (see FIG. 29) according to one or more embodiments may include the display device 100 described above.

In addition, the electronic device 10 (see FIG. 29) according to one or more embodiments may further include modules or devices having other additional functions in addition to the display device 100.

FIG. 29 is a block diagram of an electronic device according to one or more embodiments.

Referring to FIG. 29, the electronic device 10 according to one or more embodiments may include a display module 21, a processor 22, a memory 23, and a power module 24.

The display module 21 may include the display device 100 for displaying an image.

The processor 22 may include at least one of a central processing unit (CPU), an application processor (AP), a graphic processing unit (GPU), a communication processor (CP), an image signal processor (ISP), and/or a controller.

The memory 23 may store data information necessary for an operation of the processor 22 or the display module 21. When the processor 22 executes an application stored in the memory 23, an image data signal and/or an input control signal may be transmitted to the display module 21, and the display module 21 may process the received signal and output image information through a display screen.

The power module 24 may include a power supply module such as a power adapter or a battery device and a power conversion module for converting power supplied by the power supply module to generate power necessary for an operation of the electronic device 10.

At least one of the respective components of the above-described electronic device 10 may be included in the display device according to the above-described embodiments. In addition, some of individual modules functionally included in one module may be included in the display device, and the others of the individual modules may be provided separately from the display device. For example, the display device may include the display module 21, and the processor 22, the memory 23, and the power module 24 may be provided in the form of other devices within the electronic device 10 rather than the display device.

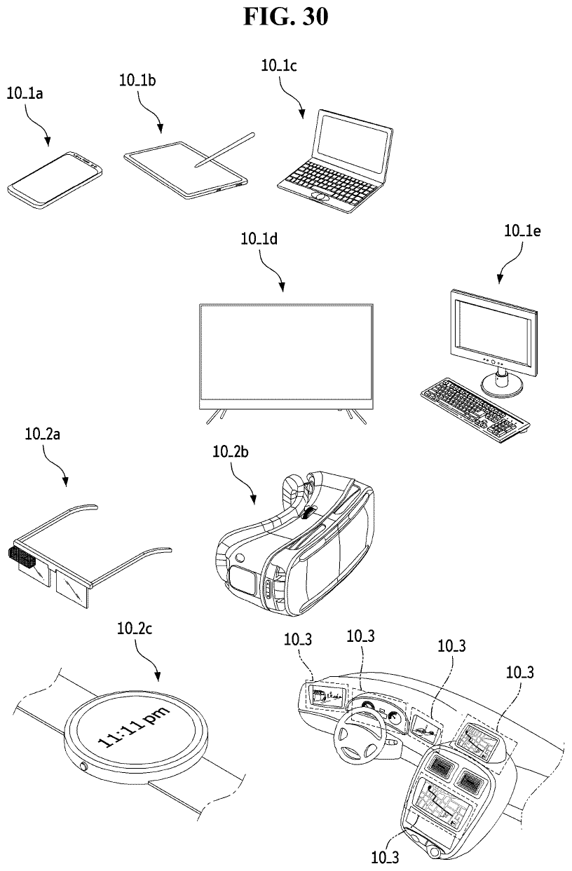

FIG. 30 is schematic views of electronic devices according to various embodiments.

Referring to FIG. 30, electronic devices 10 (see FIG. 29) according to embodiments may include not only image display electronic devices such as a smartphone 10_1a, a tablet PC 10_1b, a laptop computer 10_1c, a television (TV) 10_1d, and a monitor 10_1e for a desktop computer, but also wearable electronic devices such as a smart glasses 10_2a, a head mounted display 10_2b, and a smart watch 10_2c, and vehicle electronic devices 1_3 such as a center information display (CID) of an instrument board, a center fascia, or a dashboard of a vehicle and a room mirror display.

However, the effects, aspects, and features of the present disclosure are not restricted to the one set forth herein. The above and other effects, aspects, and features of the present disclosure will become more apparent to one of daily skill in the art to which the present disclosure pertains by referencing the claims and their equivalents.

What is claimed is:

1. A display device comprising:
a substrate including a display area where emission areas are arranged;
a circuit layer on the substrate; and
an element layer on the circuit layer,
wherein the circuit layer comprises:
a light blocking conductive layer on the substrate;
a buffer layer covering the light blocking conductive layer;
a first semiconductor layer on the buffer layer;
a first interlayer insulating layer on the first semiconductor layer; and
a second semiconductor layer on the first interlayer insulating layer and comprising an oxide semiconductor material.

2. The display device of claim 1, wherein the element layer comprises light emitting elements in the emission areas,
wherein the circuit layer comprises light emitting pixel drivers respectively transmitting driving currents to the light emitting elements,
wherein each of the light emitting pixel drivers comprises a first transistor configured to generate the driving current,
wherein the first transistor comprises a gate electrode, a channel portion overlapping the gate electrode, a first electrode portion connected to one side of the channel portion, and a second electrode portion connected to an other side of the channel portion, and
wherein the channel portion, the first electrode portion, and the second electrode portion of the first transistor are at the second semiconductor layer.

3. The display device of claim 2, wherein each of the light emitting pixel drivers further comprises:
a second transistor electrically connected between a data line configured to transmit a data signal and the gate electrode of the first transistor;
a third transistor electrically connected between a reference voltage line configured to transmit a reference voltage and the gate electrode of the first transistor;
a fourth transistor electrically connected between an initialization voltage line configured to transmit an initialization voltage and one of the light emitting elements;
a fifth transistor electrically connected between a first power line configured to transmit a first power and the first electrode portion of the first transistor;
a sixth transistor electrically connected between the one of the light emitting elements and the second electrode portion of the first transistor;
a first capacitor electrically connected between the gate electrode of the first transistor and the second electrode portion of the first transistor; and
a second capacitor electrically connected between the first power line configured to transmit the first power and the second electrode portion of the first transistor,
wherein a channel portion, a first electrode portion, and a second electrode portion of each of the second transistor, the third transistor, and the fourth transistor are at the second semiconductor layer, and
wherein a channel portion, a first electrode portion, and a second electrode portion of each of the fifth transistor and the sixth transistor are at the first semiconductor layer.

4. The display device of claim 3, wherein the circuit layer further comprises:
a first gate insulating layer covering the first semiconductor layer;
a first gate conductive layer on the first gate insulating layer;
a second gate insulating layer covering the first gate conductive layer;
a second gate conductive layer located between the second gate insulating layer and the first interlayer insulating layer;
a third gate insulating layer covering the second semiconductor layer; and
a third gate conductive layer located between the third gate insulating layer and a second interlayer insulating layer,
wherein each of the light emitting pixel drivers further comprises:
a first capacitor electrode at the first gate conductive layer and electrically connected to the gate electrode of the first transistor;
a second capacitor electrode at the first gate conductive layer, spaced from the first capacitor electrode, overlapping the first electrode portion of the sixth transistor, and electrically connected to the first power line; and
a third capacitor electrode at the second gate conductive layer, overlapping the first capacitor electrode and the second capacitor electrode, and electrically connected to the second electrode portion of the first transistor and the first electrode portion of the sixth transistor,
wherein the gate electrode of the first transistor is at the third gate conductive layer,
wherein the first capacitor is formed in an overlapping area between the first capacitor electrode and the third capacitor electrode, and
wherein the second capacitor is formed in an overlapping area between the second capacitor electrode and the third capacitor electrode.

5. The display device of claim 4, wherein each of at least some of the light emitting pixel drivers further comprises a fourth capacitor electrode located at the light blocking conductive layer, overlapping the second capacitor electrode, and electrically connected to the first power line, and
wherein the second capacitor is further located in an overlapping area between one of the first electrode portion of the sixth transistor and the second capacitor electrode and the fourth capacitor electrode.

6. The display device of claim 5, wherein the emission areas comprise:
a first emission area configured to emit light of a first wavelength band;
a second emission area configured to emit light of a second wavelength band lower than the first wavelength band; and
a third emission area configured to emit light of a third wavelength band lower than the second wavelength band,
wherein the light emitting pixel drivers comprise:
a first light emitting pixel driver electrically connected to a light emitting element of the first emission area;
a second light emitting pixel driver electrically connected to a light emitting element of the second emission area; and
a third light emitting pixel driver electrically connected to a light emitting element of the third emission area,
wherein the fourth capacitor electrode of the first light emitting pixel driver from among the at least some of the light emitting pixel drivers has a first width,
wherein the fourth capacitor electrode of the third light emitting pixel driver from among the at least some of the light emitting pixel drivers has a second width smaller than the first width, and
wherein the fourth capacitor electrode of the second light emitting pixel driver from among the at least some of the light emitting pixel drivers has a third width smaller than the second width.

7. The display device of claim 5, wherein the display area includes:
a main display area where the emission areas are arranged side by side with each other; and
at least one sub-display area surrounded by the main display area,
wherein the at least one sub-display area includes the emission areas and light transmitting areas located between the emission areas, and
wherein at least some of the light emitting pixel drivers are electrically connected to light emitting elements in the emission areas of the at least one sub-display area.

8. The display device of claim 5, wherein the circuit layer further comprises:
a first source-drain conductive layer on the second interlayer insulating layer;
a first planarization layer covering the first source-drain conductive layer;
a second source-drain conductive layer on the first planarization layer; and
a second planarization layer covering the second source-drain conductive layer, wherein the first power line comprises:
a power sub-line at the first gate conductive layer and extending in a first direction; and
a power main line at the second source-drain conductive layer and extending in a second direction crossing the first direction,
wherein the second capacitor electrode is a portion of the power sub-line, and
wherein the power main line is electrically connected to the power sub-line and the fourth capacitor electrode through a power connection electrode at the first source-drain conductive layer.

9. The display device of claim 4, wherein the channel portion of the first transistor overlaps the first capacitor electrode, the third capacitor electrode, and the gate electrode of the first transistor.

10. The display device of claim 4, wherein the circuit layer further comprises:
a bias voltage line at the light blocking conductive layer and configured to transmit a bias voltage;
a reset control line at the third gate conductive layer and configured to transmit a reset control signal; and
an initialization control line at the third gate conductive layer and configured to transmit an initialization control signal,
wherein a gate electrode of the third transistor is electrically connected to the reset control line,
wherein a gate electrode of the fourth transistor is electrically connected to the initialization control line, and wherein in each of at least some of the light emitting pixel drivers,
the channel portion of the third transistor overlaps the gate electrode of the third transistor and a portion of the reset control line, and
the channel portion of the fourth transistor overlaps the gate electrode of the fourth transistor and another portion of the bias voltage line.

11. The display device of claim 10, wherein the display area includes:
a main display area where the emission areas are arranged side by side with each other; and
at least one sub-display area surrounded by the main display area, wherein the at least one sub-display area includes the emission areas and light transmitting areas located between the emission areas, and
wherein at least some of the light emitting pixel drivers are electrically connected to light emitting elements in the emission areas of the at least one sub-display area.

12. The display device of claim 4, wherein the circuit layer further comprises:
a bias voltage line disposed at the light blocking conductive layer and configured to transmit a bias voltage;
a first emission control line at the first gate conductive layer and configured to transmit a first emission control signal; and
a second emission control line at the first gate conductive layer and configured to transmit a second emission control signal,
wherein a gate electrode of the fifth transistor is electrically connected to the first emission control line,
wherein a gate electrode of the sixth transistor is electrically connected to the second emission control line, and
wherein in each of at least some of the light emitting pixel drivers,
the channel portion of the fifth transistor overlaps the gate electrode of the fifth transistor and a portion of the bias voltage line, and
the channel portion of the sixth transistor overlaps the gate electrode of the sixth transistor and another portion of the bias voltage line.

13. The display device of claim 12, wherein the display area includes:
a main display area where the emission areas are arranged side by side with each other; and
at least one sub-display area surrounded by the main display area,
wherein the at least one sub-display area includes the emission areas and light transmitting areas located between the emission areas, and
wherein at least some of the light emitting pixel drivers are electrically connected to light emitting elements in the emission areas of the at least one sub-display area.

14. An electronic device comprising:
a display device configured to display an image;
a memory configured to store an application;
a processor configured to execute the application and configured to transmit an image data signal and an input control signal to the display device; and
a power module configured to transmit power to the display device, wherein the display device comprises:
a substrate including a display area where emission areas are arranged;
a circuit layer on the substrate; and
an element layer on the circuit layer, and
wherein the circuit layer comprises:
a light blocking conductive layer on the substrate;
a buffer layer covering the light blocking conductive layer;
a first semiconductor layer on the buffer layer;
a first interlayer insulating layer on the first semiconductor layer; and
a second semiconductor layer on the first interlayer insulating layer and comprising an oxide semiconductor material.

15. The electronic device of claim 14, wherein the element layer comprises light emitting elements in the emission areas,
wherein the circuit layer comprises:
light emitting pixel drivers configured to respectively transmit driving currents to the light emitting elements; and
a bias voltage line at the light blocking conductive layer and configured to transmit a bias voltage,
wherein each of the light emitting pixel drivers comprises a first transistor configured to generate the driving current,
wherein the first transistor comprises a gate electrode, a channel portion overlapping the gate electrode, a first electrode portion connected to one side of the channel portion, and a second electrode portion connected to an other side of the channel portion, and
wherein the channel portion, the first electrode portion, and the second electrode portion of the first transistor are at the second semiconductor layer.

16. The electronic device of claim 15, wherein each of the light emitting pixel drivers further comprises:
a second transistor electrically connected between a data line configured to transmit a data signal and the gate electrode of the first transistor;
a third transistor electrically connected between a reference voltage line configured to transmit a reference voltage and the gate electrode of the first transistor;
a fourth transistor electrically connected between an initialization voltage line configured to transmit an initialization voltage and one of the light emitting elements;
a fifth transistor electrically connected between a first power line configured to transmit a first power and the first electrode portion of the first transistor;
a sixth transistor electrically connected between the one of the light emitting elements and the second electrode portion of the first transistor;
a first capacitor electrically connected between the gate electrode of the first transistor and the second electrode portion of the first transistor; and
a second capacitor electrically connected between the first power line configured to transmit the first power and the second electrode portion of the first transistor,
the circuit layer further comprises:
a first gate insulating layer covering the first semiconductor layer;
a first gate conductive layer on the first gate insulating layer;
a second gate insulating layer covering the first gate conductive layer;
a second gate conductive layer between the second gate insulating layer and the first interlayer insulating layer;
a third gate insulating layer covering the second semiconductor layer; and
a third gate conductive layer between the third gate insulating layer and a second interlayer insulating layer,
each of the light emitting pixel drivers further comprises:
a first capacitor electrode at the first gate conductive layer and electrically connected to the gate electrode of the first transistor;
a second capacitor electrode at the first gate conductive layer, spaced from the first capacitor electrode, overlapping the first electrode portion of the sixth transistor, and electrically connected to the first power line; and
a third capacitor electrode at the second gate conductive layer, overlapping the first capacitor electrode and the second capacitor electrode, and electrically connected to the second electrode portion of the first transistor and the first electrode portion of the sixth transistor,
wherein the gate electrode of the first transistor is at the third gate conductive layer,
wherein the first capacitor is in an overlapping area between the first capacitor electrode and the third capacitor electrode, and
wherein the second capacitor is in an overlapping area between the second capacitor electrode and the third capacitor electrode.

17. The electronic device of claim 16, wherein each of at least some of the light emitting pixel drivers further comprises a fourth capacitor electrode at the light blocking conductive layer, overlapping the second capacitor electrode, and electrically connected to the first power line, and
wherein the second capacitor is further located in an overlapping area between one of the first electrode portion of the sixth transistor and the second capacitor electrode and the fourth capacitor electrode.

18. The electronic device of claim 17, wherein the emission areas include:
a first emission area configured to emit light of a first wavelength band;
a second emission area configured to emit light of a second wavelength band lower than the first wavelength band; and
a third emission area configured to emit light of a third wavelength band lower than the second wavelength band,
the light emitting pixel drivers comprise:
a first light emitting pixel driver electrically connected to a light emitting element of the first emission area;
a second light emitting pixel driver electrically connected to a light emitting element of the second emission area; and
a third light emitting pixel driver electrically connected to a light emitting element of the third emission area,
wherein a fourth capacitor electrode of the first light emitting pixel driver of at least some of the light emitting pixel drivers has a first width,
wherein a fourth capacitor electrode of the third light emitting pixel driver of the at least some of the light emitting pixel drivers has a second width smaller than the first width, and
a fourth capacitor electrode of the second light emitting pixel driver of the at least some of the light emitting pixel drivers have a third width smaller than the second width.

19. The electronic device of claim 16, wherein the circuit layer further comprises:
a reset control line at the third gate conductive layer and configured to transmit a reset control signal; and
an initialization control line at the third gate conductive layer and configured to transmit an initialization control signal,
wherein a channel portion, a first electrode portion, and a second electrode portion of each of the third transistor and the fourth transistor are at the second semiconductor layer,
wherein a gate electrode of the third transistor is electrically connected to the reset control line,
wherein a gate electrode of the fourth transistor is electrically connected to the initialization control line, and
wherein in each of at least some of the light emitting pixel drivers,
the channel portion of the third transistor overlaps the gate electrode of the third transistor and a portion of the reset control line, and
the channel portion of the fourth transistor overlaps the gate electrode of the fourth transistor and another portion of the bias voltage line.

20. The electronic device of claim 16, wherein the circuit layer further comprises:
a first emission control line at the first gate conductive layer and configured to transmit a first emission control signal; and
a second emission control line at the first gate conductive layer and configured to transmit a second emission control signal,
wherein a channel portion, a first electrode portion, and a second electrode portion of each of the fifth transistor and the sixth transistor are at the first semiconductor layer,
wherein a gate electrode of the fifth transistor is electrically connected to the first emission control line,
wherein a gate electrode of the sixth transistor is electrically connected to the second emission control line, and
wherein in each of at least some of the light emitting pixel drivers,
the channel portion of the fifth transistor overlaps the gate electrode of the fifth transistor and a portion of the bias voltage line, and
the channel portion of the sixth transistor overlaps the gate electrode of the sixth transistor and another portion of the bias voltage line.
